(19) United States
(12) Patent Application Publication
(10) Pub. No.: US 2026/0324048 A1
(43) Pub. Date: Oct. 15, 2026

(54) STRUCTURE AND METHOD FOR SEMICONDUCTOR DEVICES HAVING ENGINEERED NANOSHEETS

(71) Applicant: Taiwan Semiconductor Manufacturing Company, Ltd., Hsin-Chu (TW)

(72) Inventors: Po-Kang HO, Taipei City (TW); Chu-Yen HSIAO, Taoyuan City (TW); Tsai-Yu HUANG, Hsinchu (TW); Chien-Hao CHEN, Hsinchu (TW)

(21) Appl. No.: 19/416,380

(22) Filed: Dec. 11, 2025

Related U.S. Application Data
(60) Provisional application No. 63/788,393, filed on Apr. 14, 2025.

(51) Int. Cl. H10D 84/01; H10D 84/85

(52) U.S. Cl. CPC H10D 84/017; H10D 84/0188; H10D 84/851

(57) ABSTRACT

A method includes forming a first and second active regions in a first and second areas of a substrate respectively, each of the first and second active regions including channel layers and sacrificial layers alternatingly stacked; forming an isolation feature disposed between the first and second active regions; recessing portions of the first and second active regions to form a first and second recesses, respectively; epitaxially growing a first-type and a second-type source/drain features in the first and second recesses, respectively; forming a block layer to cover the first-type and second-type source/drain features; performing a laser annealing process to the second-type source/drain feature; forming a patterned mask layer over the block layer and covering the first-type source/drain feature; performing an ion implantation process to introduce a dopant into the second-type source/drain feature; and performing a rapid thermal annealing process to the first-type and second-type source/drain features.

### PRIORITY

This application claims the benefit to U.S. Provisional Application Ser. No. 63/788,393 filed Apr. 14, 2025, the entire disclosures of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing, and for these advancements to be realized, similar developments in IC processing and manufacturing are needed.

For example, multi-gate devices have been introduced in an effort to improve gate control by increasing gate-channel coupling; and reduce OFF-state current. One such multi-gate device is a gate-all-around (GAA) transistor, whose gate structure extends around its channel region, thereby providing access to the channel region on all sides. Such GAA transistors are compatible with conventional complementary metal-oxide-semiconductor (CMOS) processes, allowing them to be aggressively scaled down while maintaining gate control and mitigating SCEs. However, conventional methods for GAA devices may experience challenges, including dopant diffusion from the source/drain region, variation of channel lengths, degraded doping profile, and short-channel effects (SCEs), especially as device size is scaled down. Therefore, although conventional GAA devices have been generally adequate for their intended purposes, they are not satisfactory in every respect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C and 1D are flow charts of an example method for fabricating an embodiment of a device structure according to some embodiments of the present disclosure;

FIGS. 2A to 6A and 8A to 16A are top views of the present disclosure constructed at various fabrication stages according to some embodiments of the present disclosure;

FIGS. 2B to 6B and 8B to 16B are cross sectional views of a device structure of the present disclosure along the line A-A′ in FIGS. 2A to 6A and 8A to 16A, respectively, according to some embodiments of the present disclosure;

FIGS. 2C to 6C and 8C to 16C are cross sectional views of an embodiment of a device structure of the present disclosure along the line B-B′ in FIGS. 2A to 6A and 8A to 16A, respectively, according to some embodiments of the present disclosure;

FIGS. 2D to 6D and 8D to 16D are cross sectional views of an embodiment of a device structure of the present disclosure along the line C-C′ in FIGS. 2A to 6A and 8A to 16A, respectively, according to some embodiments of the present disclosure;

FIGS. 7A to 7P are cross-sectional views of example methods for fabricating various embodiments of a device structure according to some embodiments of the present disclosure; and

FIGS. 7Q and 7R illustrate diagrammatic view of a device structure according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm.

Multi-gate devices (e.g. gate-all-around (GAA) devices) have been introduced in an effort to improve gate control by increasing gate-channel coupling and reduce OFF-state current. GAA devices can be aggressively scaled down while maintaining gate control and mitigating SCEs. However, conventional methods for GAA devices may experience challenges, including dopant diffusion and nonuniform dopant profile, and reduced channel length due to the dopant diffusion and uneven channel length, poor epitaxial growth in the source/drain region, small formation margin for gate dielectric and electrode in the narrow channel-channel spaces, channel degradations related to various etch residues, defects and dopant diffusion. These drawbacks are exacerbated as device size is scaled down.

The present disclosure is generally related to ICs and semiconductor devices and methods of forming the same. More particularly, the present disclosure is related to nanosheet devices having nanosheets vertically stacked and a gate structure wrapping around the nanosheets. The nanosheet devices include ga-all-around (GAA) devices. A GAA device includes any device that has its gate structure, or portions thereof, formed around all-sides of a channel region (e.g. surrounding a portion of a channel region). In some instances, a GAA device may also be referred to as a quad-gate device where the channel region has four sides and the gate structure is formed on all four sides. The channel region of a GAA device may include one or more semiconductor layers, each of which may be in one of many different shapes, such as wire (or nanowire), sheet (or nanosheet), bar (or nano-bar), and/or other suitable shapes. In embodiments, the channel region of a GAA device may have multiple horizontal semiconductor layers (such as nanowires, nanosheets, or nano-bars) (hereinafter collectively referred to as “nanochannels”) vertically spaced, making the GAA device a stacked horizontal GAA device. The GAA devices presented herein may be a complementary metal-oxide-semiconductor (CMOS) GAA device, a p-type metal-oxide-semiconductor (pMOS) GAA device, an n-type metal-oxide-semiconductor (nMOS) GAA device, or a complementary field-effect transistor (CFET) having nMOS and pMOS transistors vertically stacked. Further, the GAA devices may have one or more channel regions associated with a single, contiguous gate structure, or multiple gate structures. One of ordinary skill may recognize other examples of semiconductor devices that may benefit from aspects of the present disclosure. For example, other types of metal-oxide semiconductor field effect transistors (MOSFETs), such as planar MOSFETs, FinFETs, other multi-gate FETs may benefit from the present disclosure. The GAA devices and methods of manufacture that are proposed in the present disclosure exhibit desirable properties, examples being: (1) a process using dummy interposer or dummy oxide interposer (DOI); (2) various annealing processes designed to reduce degradation of doping profile; and (3) improved channel doping uniformity and channel length uniformity.

In the illustrated embodiments, the IC device includes a device structure (or GAA device or workpiece) 100. The device structure 100 may be fabricated during processing of the IC, or a portion thereof, that may include static random access memory (SRAM), oscillator ring, logic circuits, passive components such as resistors, capacitors, and inductors, and active components such as p-type field effect transistors (pFETs), n-type FETs (nFETs), FinFETs, MOSFETs, CMOS, bipolar transistors, high voltage transistors, high frequency transistors, other memory cells, and combinations thereof.

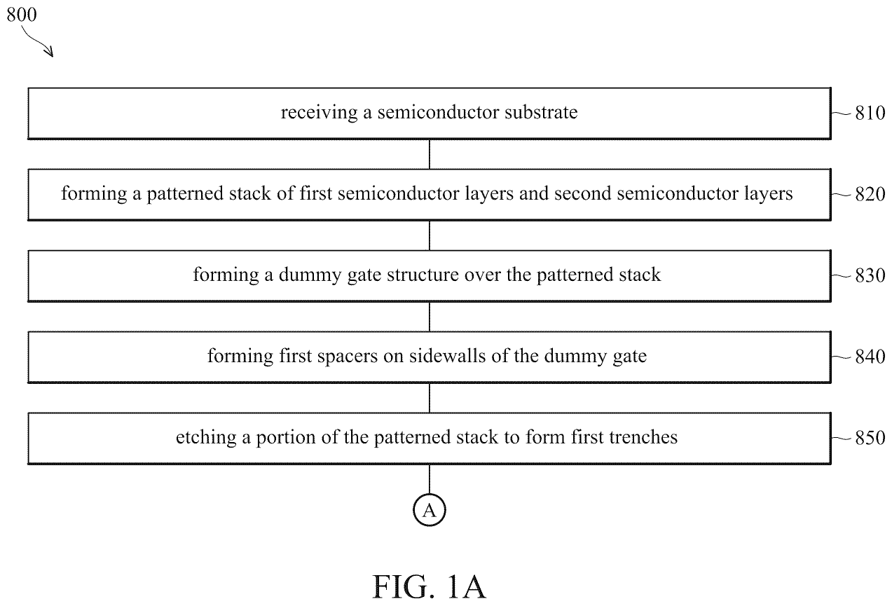

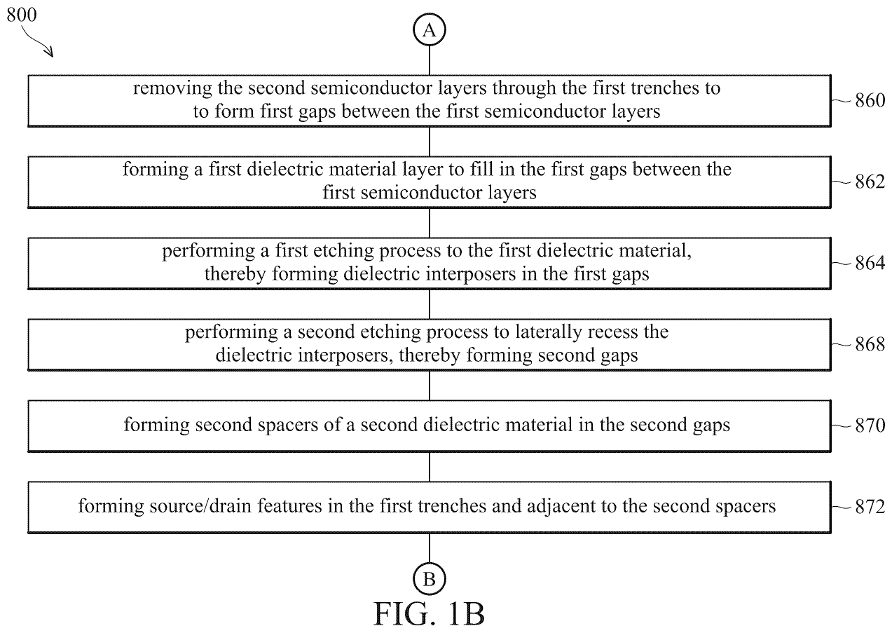

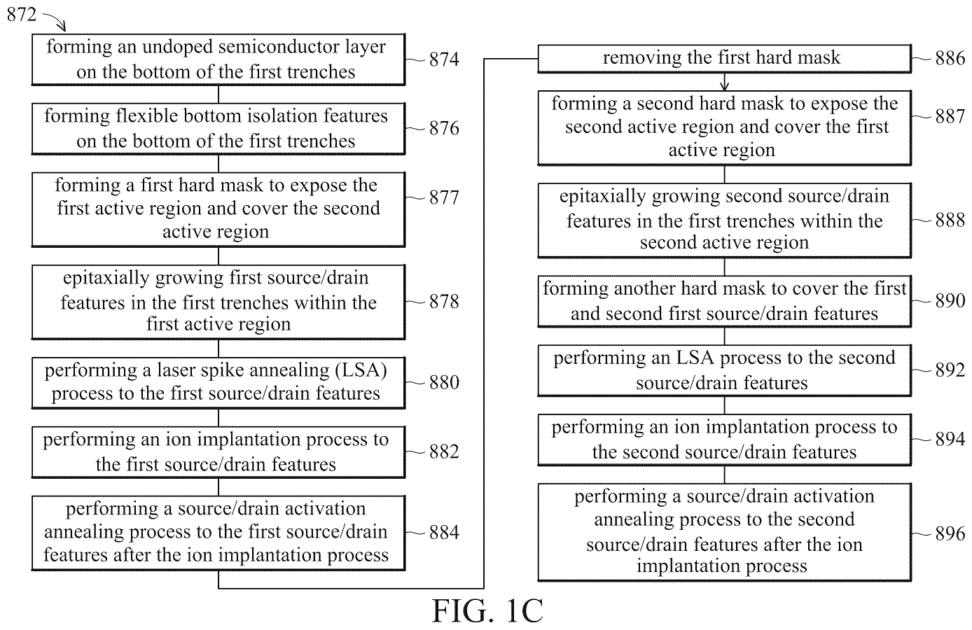

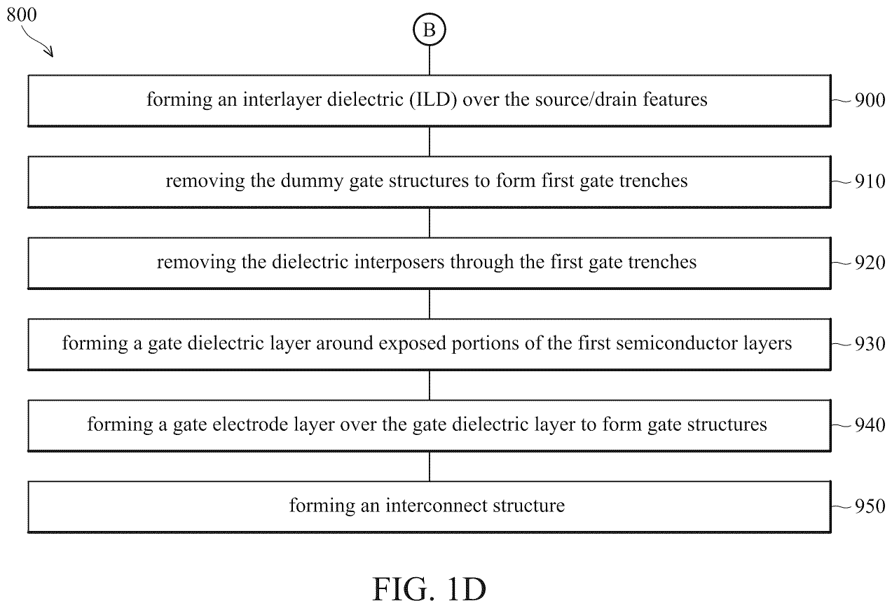

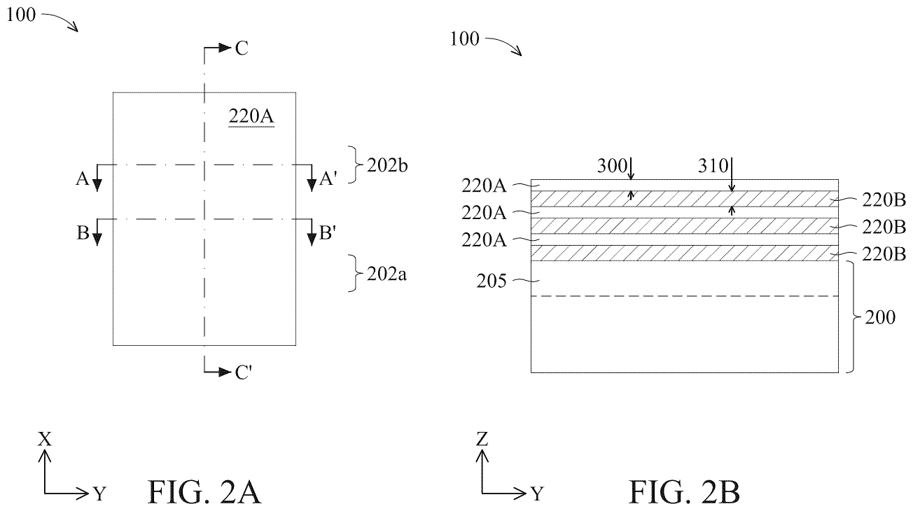

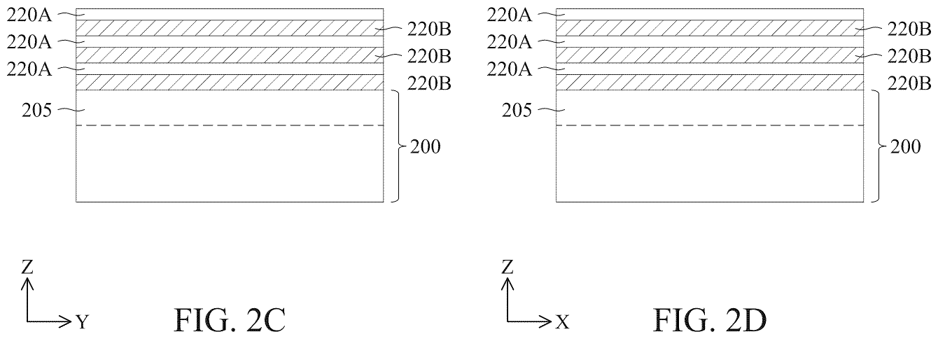

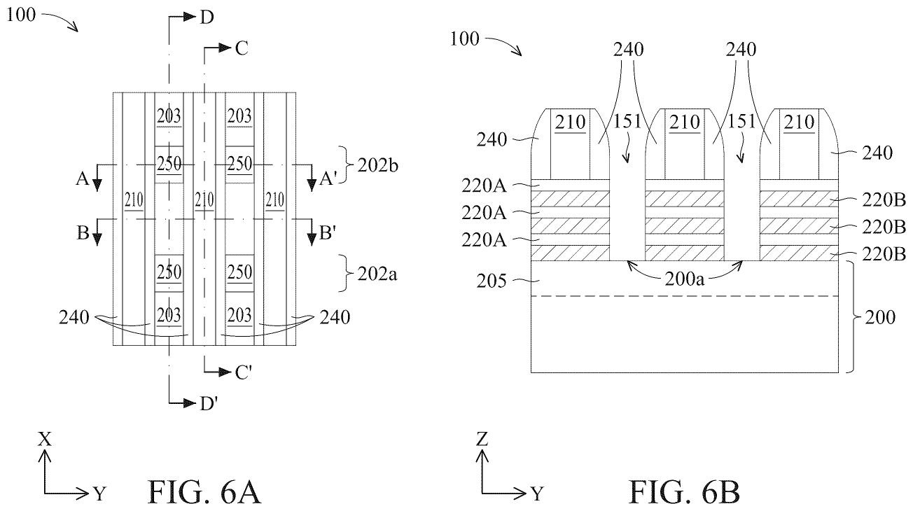

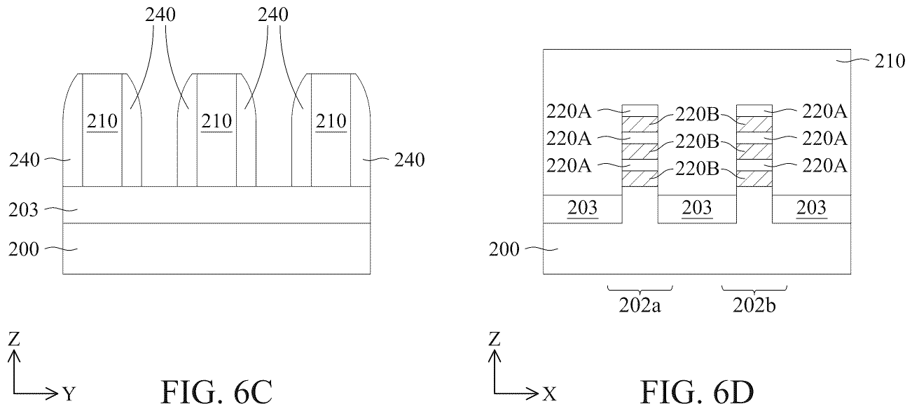

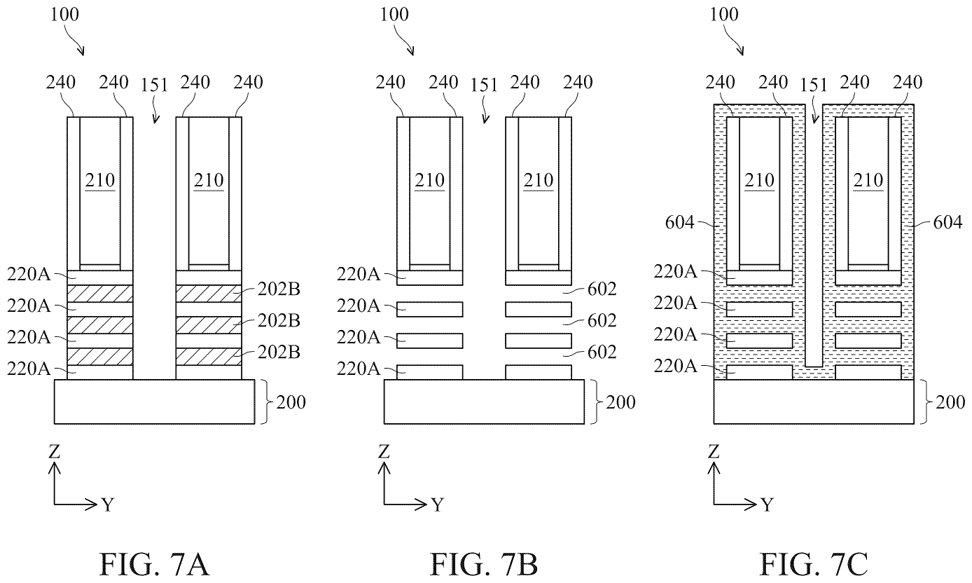

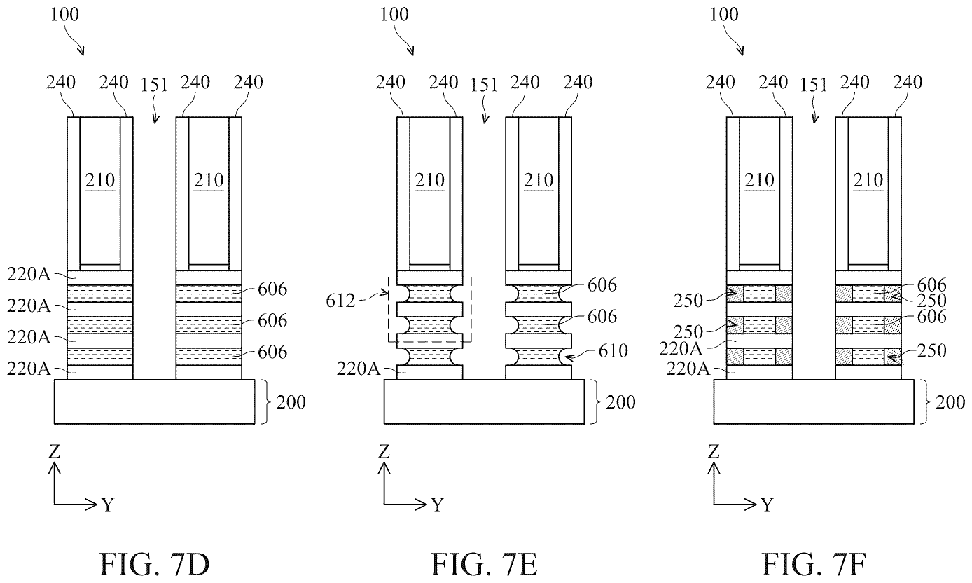

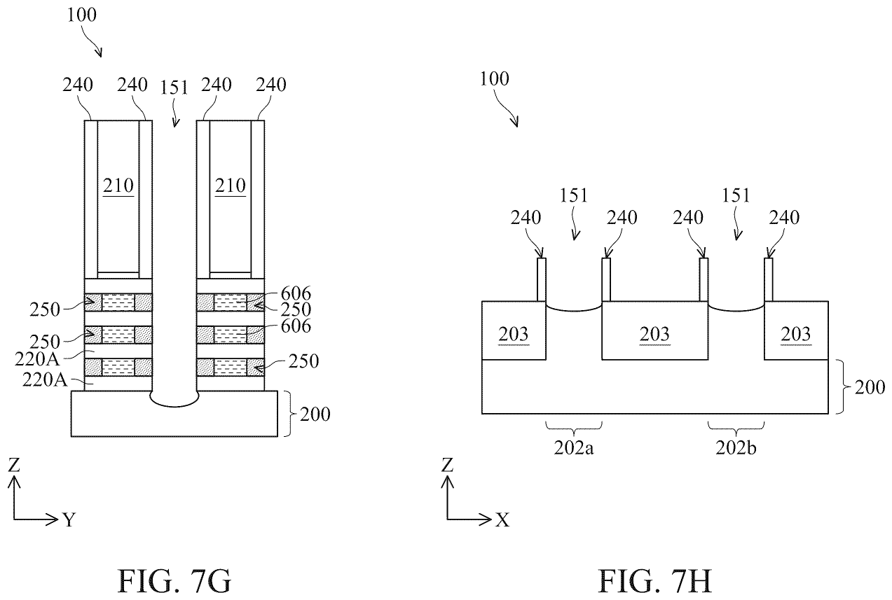

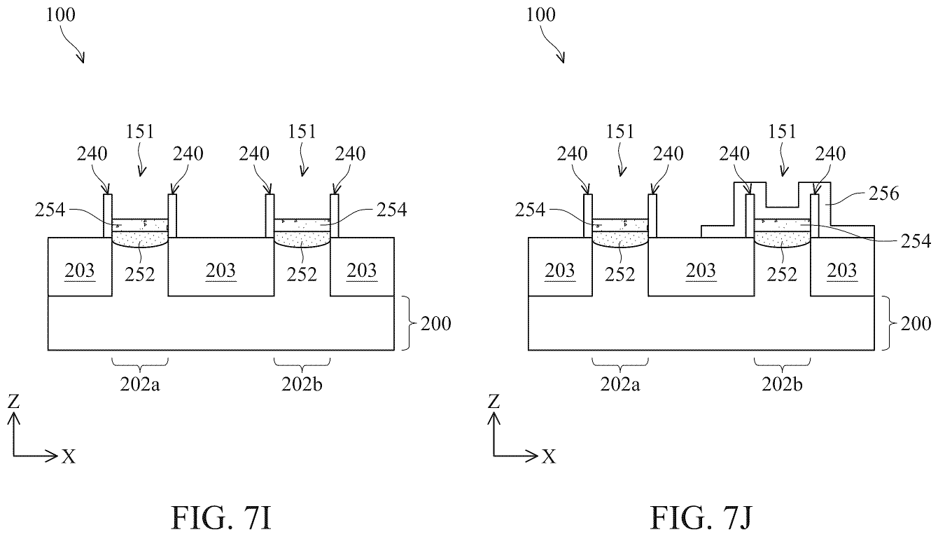

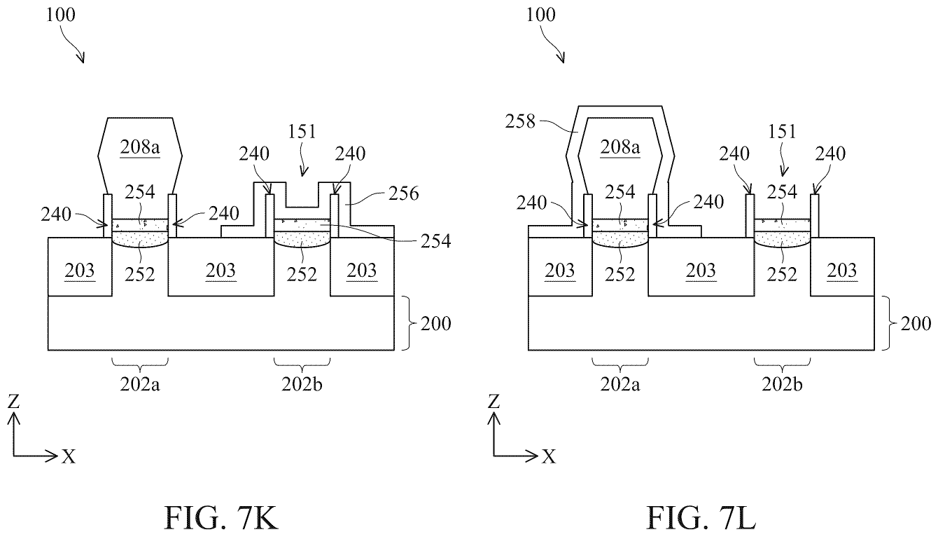

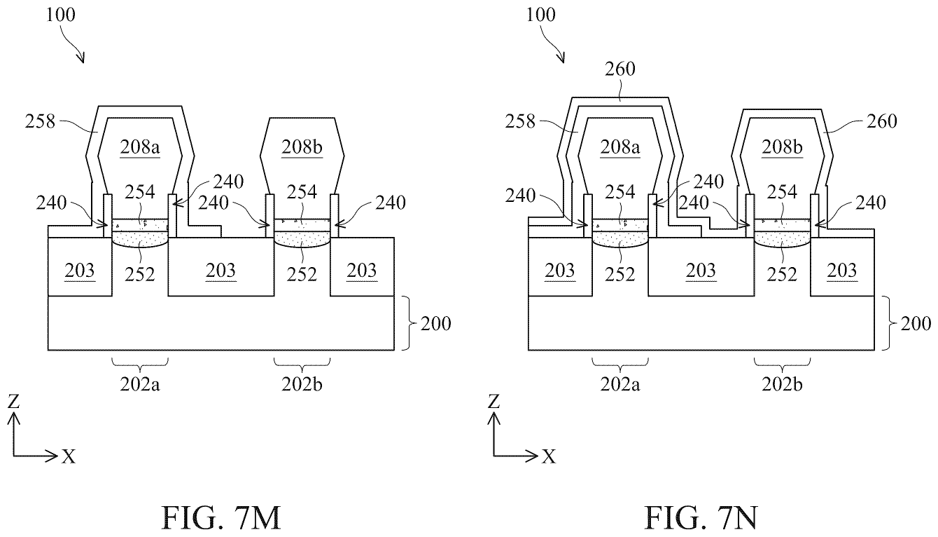

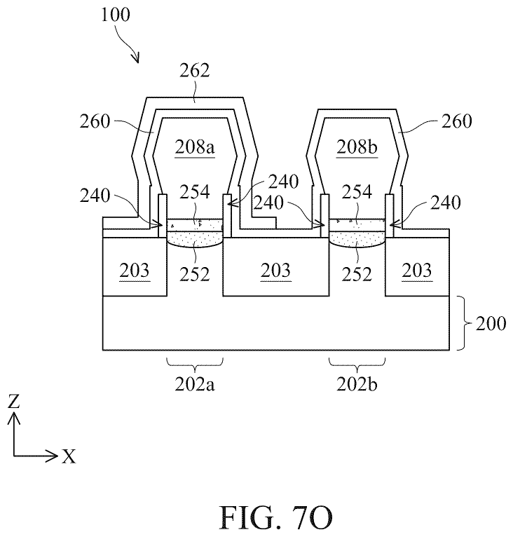

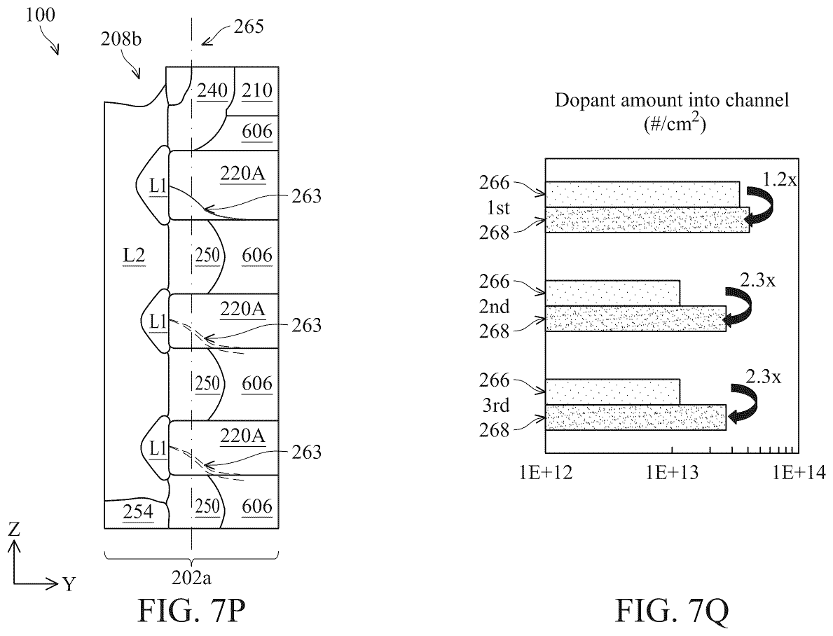

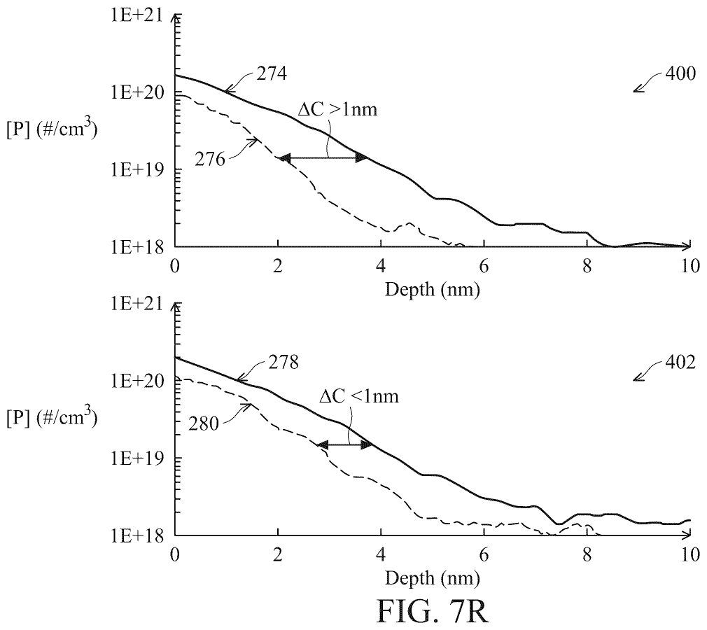

FIGS. 1A-1D are flowcharts of an example method for fabricating an embodiment of a device structure (or a semiconductor structure) according to some embodiments of the present disclosure. FIGS. 2A to 6A and 8A to 16A are top views of an embodiment of the present disclosure constructed at various fabrication stages according to some embodiments of the present disclosure. FIGS. 2B to 6B and 8B to 16B, FIGS. 2C to 6C and 8C to 16C, FIGS. 2D to 6D and 8D to 16D are cross sectional views of an embodiment of a device structure of the present disclosure along the lines A-A′, B-B′, and C-C′ in FIGS. 2A to 6A and 8A to 16A, respectively, according to some embodiments of the present disclosure. FIGS. 7A to 7G are cross-sectional views of a device structure along the line A-A′ in FIG. 6A, in portion or entirety, according to some embodiments of the present disclosure. FIGS. 7H to 7P are cross-sectional views of a device structure along the line D-D′ in FIG. 6A, in portion or entirety, according to some embodiments of the present disclosure. FIGS. 7Q to 7R are diagrammatic views of a device structure according to some embodiments of the present disclosure.

Referring to block 810 of FIG. 1A and FIGS. 2A-2D, the device structure 100 includes a substrate 200. In some embodiments, the substrate 200 contains a semiconductor material, such as bulk silicon (Si). Alternatively or additionally, another elementary semiconductor, such as germanium (Ge) in a crystalline structure, may also be included in the substrate 200. The substrate 200 may also include a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. The substrate 200 may also include a semiconductor-on-insulator substrate, such as Si-on-insulator (SOI), SiGe-on-insulator (SGOI), Ge-on-insulator (GOI) substrates. Portions of the substrate 200 may be doped, such as the doped regions 205. The doped regions 205 may be doped with p-type dopants, such as boron (B) or boron fluoride (BF₃), or doped with n-type dopants, such as phosphorus (P) or arsenic (As). The doped portions 205 may also be doped with combinations of p-type and n-type dopants (e.g. to form a p-type well and an adjacent n-type well). The doped portions 205 may be formed directly on the substrate 200, in a p-well structure, in an n-well structure, in a dual-well structure, or using a raised structure.

At block 820, a patterned stack of semiconductor layers is formed. Particularly, referring to block 820 of FIG. 1A and FIGS. 2A-2D, a stack of semiconductor layers 220A and 220B are formed over the substrate 200 in an interleaving or alternating fashion, extending vertically (e.g. along the Z-direction) from the substrate 200. For example, a semiconductor layer 220B is disposed over the substrate 200, a semiconductor layer 220A is disposed over the semiconductor layer 220B, another semiconductor layer 220B is disposed over the semiconductor layer 220A, so on and so forth. In the depicted embodiments, there are three layers of semiconductor layers 220A and three layers of semiconductor layers 220B alternating between each other. However, there may be any appropriate number of layers in the stack. For example, there may be 2 to 10 layers of semiconductor layers 220A, alternating with 2 to 10 layers of semiconductor layers 220B in the stack. For convenience, the semiconductor layers 220A and 220B are also referred to as the first semiconductor layers 220A and the second semiconductor layers 220B, respectively. The material compositions of the semiconductor layers 220A and 220B are configured such that they have an etching selectivity in a subsequent etching process. For example, in some embodiments, the semiconductor layers 220A contain silicon germanium (SiGe), while the semiconductor layers 220B contain silicon (Si). In some other embodiments, the semiconductor layers 220B contain SiGe, while the semiconductor layers 220A contain Si. In the depicted embodiment, each of the semiconductor layers 220A has a substantially uniform thickness, depicted in FIG. 2B as the thickness 300, while each of the semiconductor layers 220B has a substantially uniform thickness, depicted in FIG. 2B as the thickness 310. The semiconductor layers 220A are nano sheets and eventually function as channels. Their composition is designed to fit the design of the various devices formed thereon. In the disclosed embodiment, the semiconductor layers 220A are undoped, such as undoped silicon or alternatively undoped SiGe.

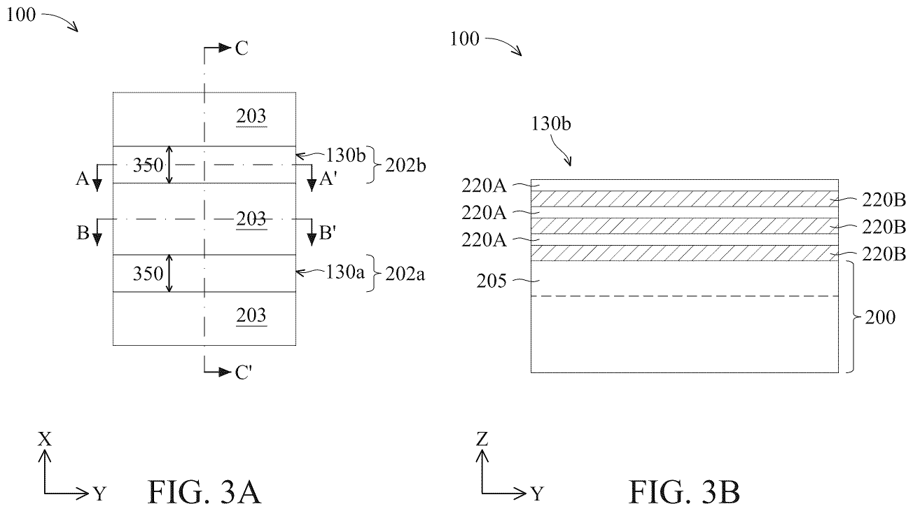

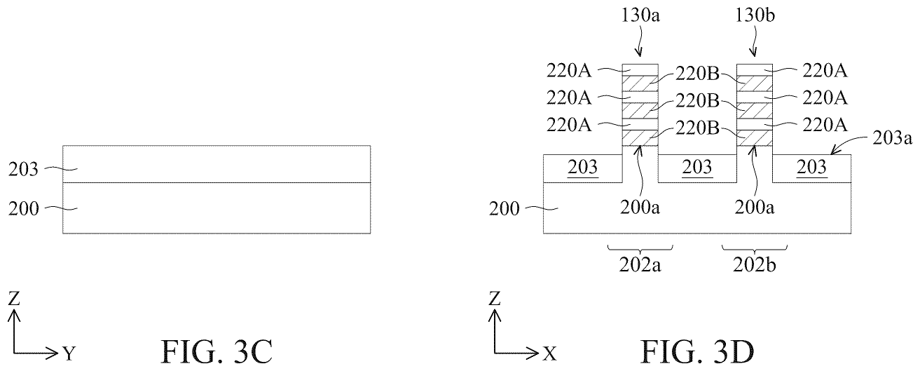

Referring to block 820 of FIG. 1A and FIGS. 3A-3D, the stack of semiconductor layers 220A and 220B is patterned into a plurality of active regions (such as fin active regions or simply fin structures or fins), for example, into active regions 130a and 130b. Each of the active regions 130a and 130b includes a stack of semiconductor layers 220A and 220B disposed in an alternating manner with respect to one another. The active regions 130a and 130b each extend lengthwise (e.g. longitudinally) in a first direction (e.g. in the Y-direction) and are separated from each other (e.g. laterally) in a second direction (e.g. in the X-direction), as shown in FIGS. 3A and 3D. As illustrated in FIG. 3A, the active regions may each have a lateral width along the X-direction, depicted in FIG. 3A as the width 350. It is understood that the X-direction and the Y-direction are horizontal directions that are perpendicular to each other, and that the Z-direction is a vertical direction that is orthogonal (or normal) to a plane defined by the X-direction and the Y-direction. The substrate 200 may have its top surface aligned in parallel to the XY plane. In some embodiments, the active regions 130a and 130b have different widths.

The active regions 130a and 130b may be patterned by any suitable method. In the disclosed embodiments, the active regions 130a, 130b are protruding above the substrate 200, therefore are also referred to as active fins (or simply fins). For example, the active regions may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the stack of the semiconductor layers 220A, 220B to form the fins 130a and 130b. The patterning may utilize multiple etching processes which may include a dry etching and/or wet etching. The regions in which the fins are formed will be used to form active devices through subsequent processing and are thus referred to as active regions. For example, fin 130a is formed in the active region 202a, and the fin 130b is formed in the active region 202b. Both fins 130a and 130b protrude out of the doped regions 205.

The device structure 100 includes an isolation structure 203 having various isolation features, which may be shallow trench isolation (STI) features. In some examples, the formation of the isolation features 203 includes etching trenches into the substrate 200 between the active regions and filling the trenches with one or more dielectric materials such as silicon oxide, silicon nitride, silicon oxynitride, other suitable materials, or combinations thereof. Any appropriate methods, such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof may be used for depositing the isolation features 203. The isolation features 203 may have a multi-layer structure such as a thermal oxide liner layer over the substrate 200 and a filling layer (e.g., silicon nitride or silicon oxide) over the thermal oxide liner layer. Alternatively, the isolation features 203 may be formed using any other isolation formation techniques. As illustrated in FIG. 3D, the active regions 130a and 130b are protruded above the top surface 203a of the isolation features 203 (e.g. protrude out of the isolation features 203) and are also located above the top surface 200a of the substrate 200. In some embodiments, the active regions 130a/130b and the isolation features 203 are collectively formed in a same procedure, such as a procedure that includes patterning the stack of semiconductor layers 220A and 220B to from fins and trenches; filling the trenches with one or more dielectric materials; performing a chemical mechanical polishing (CMP) process; and etching back the isolation features 203 such that the isolation features 203 are recessed below the active regions 130a and 130b.

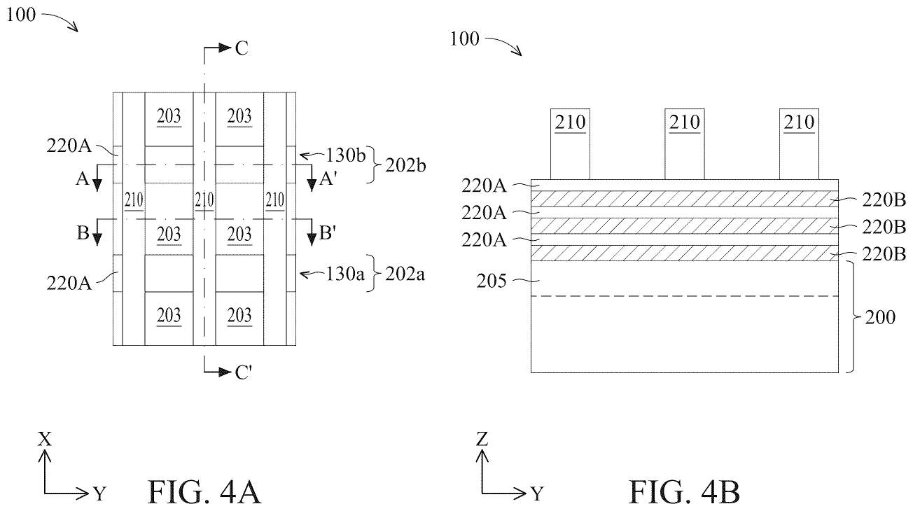

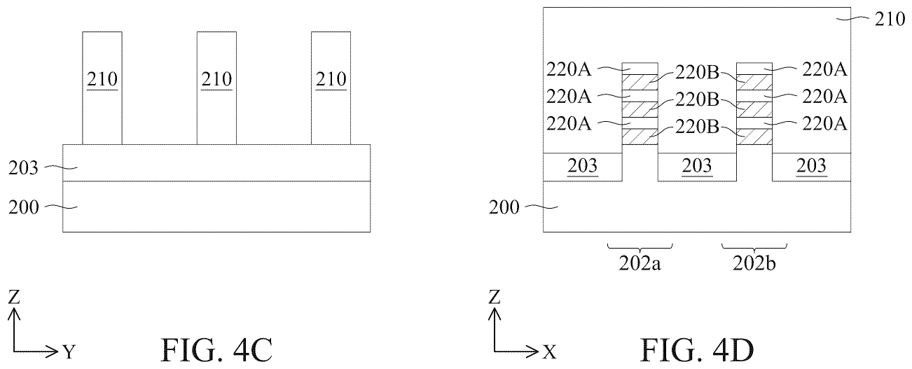

Referring to block 830 of FIG. 1A and FIGS. 4A-4D, dummy gate structures 210 are formed over a portion of each of the active regions 130a and 130b, and over the isolation features 203, in between the fins 130a and 130b. The dummy gate structures 210 may be configured to extend lengthwise (e.g. longitudinally) in parallel to each other, for example, each along the X-direction, as shown in FIG. 4A. In some embodiments, as illustrated in FIG. 4D, each of the dummy gate structures wraps around the top surface and side surfaces of each of the active regions 130a, 130b. The dummy gate structures 210 may include polysilicon. In some embodiments, dummy gate structures 210 also include one or more mask layers, which are used to pattern the dummy gate material layers. The dummy gate structures 210 may undergo a gate replacement process through subsequent processing to form metal gates, such as a high-k metal gate, as discussed in greater detail below. Some of the dummy gate structures 210 may also undergo a second gate replacement process to form a dielectric based gate that electrically isolates the device structure 100 from neighboring devices. The dummy gate structures 210 may be formed by a procedure including deposition, lithography patterning, and etching processes. The deposition processes may include CVD, ALD, PVD, other suitable methods, and/or combinations thereof.

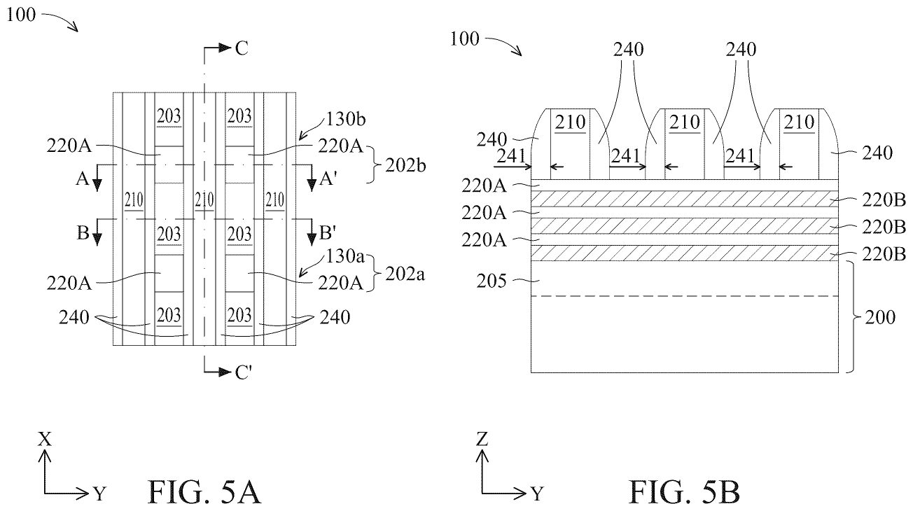

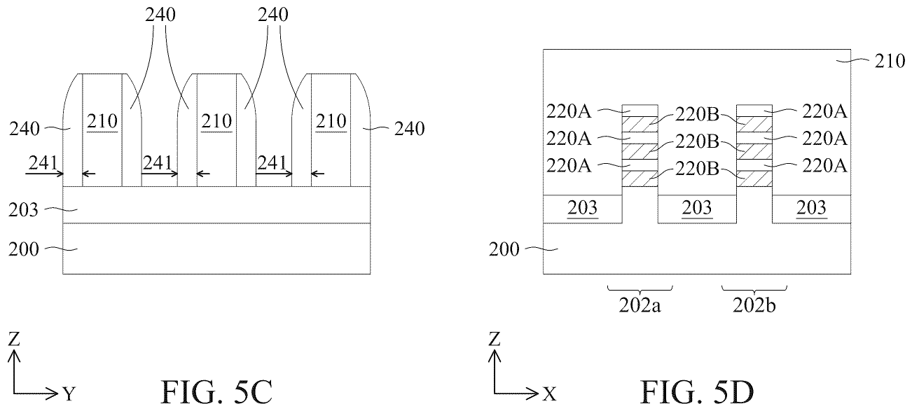

Referring to block 840 of FIG. 1A and FIGS. 5A-5D, gate spacers (or first spacers) 240 are formed on the sidewalls of the dummy gate structures 210. The gate spacers 240 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, other suitable dielectric material, or combinations thereof. The gate spacers 240 may include a single layer or a multi-layer structure. In some embodiments, each of the gate spacers 240 may have a thickness 241 (e.g. measured in the Y-direction) in a range from about 3 nm to about 10 nm. A thickness within the stated range of values may be needed for device performance, especially for advanced technology nodes. In some embodiments, the gate spacers 240 may be formed by depositing a spacer layer (containing the dielectric material) over the dummy gate structures 210, followed by an anisotropic etching process to remove portions of the spacer layer from the top surfaces of the dummy gate structures 210. After the etching process, portions of the spacer layer on the sidewall surfaces of the dummy gate structures 210 substantially remain and become the gate spacers 240. In some embodiments, the anisotropic etching process is a dry (e.g. plasma) etching process. Additionally, or alternatively, the formation of gate spacers 240 may also involve chemical oxidation, thermal oxidation, ALD, CVD, and/or other suitable methods. In the active regions, the gate spacers 240 are formed over the top layer of the semiconductor layers 220A. Accordingly, the gate spacers 240 may also be interchangeably referred to as the top spacers 240. In some examples, one or more material layers (not shown) may also be formed between the dummy gate structures 210 and the corresponding top spacers 240. The one or more material layers may include an interfacial layer and/or a high-k dielectric layer, as examples.

Referring to block 850 of FIG. 1A and FIGS. 6A-6D, portions of the active regions 130a and 130b exposed by the dummy gate structures 210 and the gate spacers 240 are at least partially recessed (or etched away) to form trenches 151 for subsequent epitaxial source and drain growth. The process used to form the trenches 151 may include one or multiple lithography and etching steps, and may use any suitable methods, such as dry etching and/or wet etching. As an example, one or more of the multiple lithography and etching steps used to form the trenches 151 may include a first etching process having a first etch chemistry and a second etching process having a second etch chemistry that is different from the first etch chemistry. The first etch process may be a main-etch process that initially forms openings in the stack of semiconductor layers 220A and 220B, while the second etch process may be an over-etch process that shapes the initially formed openings to produce the desired profile of the trenches 151, such as the trenches having vertical sidewalls. The first etch chemistry may include hydrogen bromide (HBr) combined with argon (Ar), helium (He), oxygen (O₂), or a combination thereof. The second etch chemistry may include hydrogen bromide (HBr) combined with nitrogen, methane (CH₄), or a combination thereof. The second etch process (e.g. the over-etch process) may be performed at a high bias power (e.g. a bias power in a range from about 200 Watts to about 400 Watts).

The method 800 proceeds to operations 860 through 874 in FIGS. 7A through 7G, which are associated with processing steps applied in the trenches 151 and designed to reduce residue, maintain the profile of the nanosheets or the semiconductor layers 220A and enhance the channel performance. Only FIGS. 7A through 7F in sectional views along AA′ of FIG. 6A are illustrated for simplicity. Especially, the operations 860 through 874 begin with FIG. 7A, which is similar to FIG. 6B, although the number of the semiconductor layers 220A and the number of the semiconductor layers 220B may be different. As noted above, there may be any appropriate number of layers in the stack.

Referring to block 860 of FIG. 1B and FIG. 7B, the semiconductor layers 220B are removed through the trenches 151 via a selective etching process, resulting in first gaps 602 between the semiconductor layers 220A. The selective etching process may be any suitable processes, such as a wet etching, a dry etching process or a combination thereof. In an embodiment, the semiconductor layers 220A includes Si and the semiconductor layers 220B includes SiGe. In such an embodiment, the SiGe semiconductor layers 220B are selectively etched away by a solution that includes ammonia hydroxide (NH₄OH), hydrogen peroxide (H₂O₂), and water (H₂O). For example, the SiGe semiconductor layers 220B may be etched away at a substantially faster rate than the Si semiconductor layers 220A. As a result, the semiconductor layers 220B (e.g. the side portions 220B-side) are removed, while the semiconductor layers 220A remain substantially unchanged. The optimal condition may be reached by additionally adjusting the etching temperature, dopant concentration, as well as other experimental parameters.

In another embodiment, the semiconductor layers 220A include SiGe and the semiconductor layers 220B includes Si. In such an embodiment, a cryogenic deep reactive ion etching (DRIE) process may be used to selectively etch away the Si semiconductor layer 220B. For example, the DRIE process may implement a sulfur hexafluoride-oxygen (SF₆-O₂) plasma. The optimal condition may be reached by adjusting the etching temperature, the power of the Inductively Coupled Plasma (ICP) power source and/or Radio Frequency (RF) power source, the ratio between the SF₆ concentration and the O₂ concentration, the dopant (such as boron) concentrations, as well as other experimental parameters. For example, the etching rate of a Si semiconductor layer 220B using a SF₆-O₂ plasma (with approximately 6% O₂) may exceed about 8 μm/min at a temperature of about −80° C.; while the SiGe semiconductor layers 220A are not substantially affected during the process.

Referring to block 862 of FIG. 1B and FIG. 7C, one or more dielectric material 604 is deposited to fill in the first gaps 602. The dielectric material 604 is deposited on sidewalls of the trenches 151, the sidewalls of the gate spacers 240 and the top of the gate structures 210. In some embodiments, the dielectric material 604 includes silicon oxide, silicon nitride, silicon oxynitride, any suitable dielectric material, or a combination thereof.

In some embodiments, the dielectric material 604 includes silicon oxide. The dielectric material 604 of silicon oxide may be formed by CVD, low pressure chemical vapor deposition (LPCVD), atmospheric pressure chemical vapor deposition (APCVD), flowable CVD (FCVD), thermal oxidation, other suitable method, or a combination thereof. In some examples, silicon oxide is formed by CVD using a precursor including silane (SiH4) and oxygen (O2), alternatively further including PH3 or B2H6 as dopants. The deposition temperature ranges between 400 °C and 500° C. In some examples, silicon oxide is formed by LPCVD using a precursor including tetraethoxysilane Si(OC₂H₅)₄ (TEOS) and oxygen (O₂) with a deposition temperature around 700° C., such as in a range between 650° C. and 750° C. In some examples, silicon oxide is formed by PECVD using a precursor including TEOS and ozone (O₃) with a deposition temperature ranging between 300° C. and 350° C. In some examples, silicon oxide is formed by PECVD using a precursor including SiH₄ and N₂O with a deposition temperature ranging between 200° C. and 450° C. In some examples, silicon oxide is formed by APCVD using a precursor including TEOS and O₃ with a deposition temperature ranging between 350 °C and 500 °C. In some examples, silicon oxide is formed by thermal oxidation PECVD using a precursor including SiH₄ and N₂O with a deposition temperature ranging between 200° C. and 450° C.

In the disclosed embodiment, the dielectric material layer 604 includes silicon oxide and is formed by a procedure that includes CVD and FCVD. For example, a CVD is applied to form a thin silicon oxide layer, and FCVD is applied thereafter to form another silicon oxide to completely fill the first gaps 602. In furtherance of the embodiment, the first deposition step includes forming a first silicon oxide layer by CVD using a precursor including silane (SiH₄) and oxygen (O₂) with a deposition temperature ranging between 400° C. and 500° C.; and the second deposition step includes forming a second silicon oxide layer by FCVD with details described below.

The FCVD process may include the deposition of a silicon-and-nitrogen containing film (e.g., a silicon-nitrogen-hydrogen (Si—N—H) film) from a carbon-free silicon-and-nitrogen precursor and radical precursor. Because the silicon-and-nitrogen film is formed without carbon, the conversion of the film into hardened silicon oxide is done with less pore formation and less volume shrinkage. The conversion of the silicon-and-nitrogen film to silicon oxide may be done by heating the silicon-and-nitrogen film in an oxygen-containing atmosphere. The oxygen-containing gases in this atmosphere may include radical atomic oxygen (O), molecular oxygen (O₂), ozone (O₃), and/or steam (H₂O), among other oxygen-containing gases. The heating temperatures, times, and pressures are sufficient to oxidize the silicon-and-nitrogen film into the silicon oxide film.

Referring to block 864 of FIG. 1B and FIG. 7D, an etching process (also referred to as a first etching process) is applied to the dielectric material 604, thereby removing the portions of the dielectric material 604 deposited on the sidewalls of the trenches 151, resulting in the dielectric interposers 606 in the first gaps 602. The method includes an anisotropic etch, such as a plasma etch, with etching substantially on the vertical direction. In furtherance of the embodiment, the plasma etch includes an etchant having fluorine-containing gas, chlorine-containing gas, other suitable gas or a combination thereof.

Still referring to FIG. 7D, a first wet cleaning process using a first cleaning chemical solution may be applied to device structure 100 to remove any residues, such as metal residues after the first etching process at block 864. The existing cleaning processes cause damages to the dielectric interposers 606, resulting in defects, such as voids, on the dielectric interposers 606. Other issues may also present. For example, the first semiconductor layers 220A, eventually functioning as channels of the GAA transistors, are further degraded, such as reducing the dimensions of the portions exposed to the cleaning solution. The end portions of the first semiconductor layers 220A are reduced by the cleaning solution with round corners and less dimension, which further degrades the GAA device performance and the threshold voltage. Accordingly, the cleaning solutions, and the cleaning process conditions and parameters are identified and implemented at this step and other subsequent steps to be described later.

In the disclosed embodiments, the first cleaning chemical solution includes hydrofluoric acid (HF), water (H₂O), and one or more pH adjuster. In some embodiments, the cleaning solution includes hydrofluoric acid (HF) with a volume concentration (volume ratio as a ratio of a volume of the corresponding chemical to the volume of the total cleaning solution) ranging between 0.02% and 20%, water (H₂O) with a volume concentration ranging between 60% and 99.8%, and one of a base pH adjuster and an acid pH adjuster. In some embodiments, the base adjuster includes ammonium hydroxide (NH₄OH) with a volume concentration ranging between 0% and 20%, so to tune the pH value of the cleaning solution to a pH value ranging between 5 and 12. In some embodiments, the acid adjuster includes hydrogen chloride (HCl), phosphoric acid (H₃PO₄), sulfuric acid (H₂SO₄), or a combination thereof, with a volume concentration ranging between 0% and 20%, so to tune the pH value of the cleaning solution to a pH value ranging between 1 and 6. In furtherance of the embodiments, the cleaning solution includes a temperature ranging between 5° C. and 80° C. when it is applied to the device structure 100.

In one embodiment, the first cleaning solution includes hydrofluoric acid (HF) with a volume concentration (volume ratio) ranging between 0.02% and 20%; water (H₂O) with a volume concentration ranging between 60% and 99.8%; and a base pH adjuster NH₄OH with a volume concentration ranging between 0% and 20% to tune the pH value of the cleaning solution to a pH value ranging between 5 and 12, and furthermore with a solution temperature ranging between 5° C. and 80° C. In another embodiment, the cleaning solution includes hydrofluoric acid (HF) with a volume concentration (volume ratio) ranging between 0.02% and 20%; water (H₂O) with a volume concentration ranging between 60% and 99.8%; and an acid pH adjuster containing hydrogen chloride (HCl), phosphoric acid (H₃PO₄), sulfuric acid (H₂SO₄), or a combination thereof, with a volume concentration ranging between 0% and 20% to tune the pH value of the cleaning solution to a pH value ranging between 1 and 6, and furthermore with a solution temperature ranging between 5° C. and 80° C. Such prepared cleaning solution has a high selectivity and effectiveness to clean the workpiece 100 without damages to the dielectric interposers 606 and the first semiconductor layers 220A, and without metal residues. Furthermore, the cleaning solution (such as second and third cleaning solutions, described below) is further tuned to each cleaning steps for respective effectiveness.

Referring to block 868 of FIG. 1B and FIG. 7E, an etching process (also referred to as a second etching process) is applied to the dielectric interposers 606 so that the dielectric interposers 606 are laterally recessed through the exposed sidewall surfaces in the trenches 151. The selective etching process may be any suitable etching processes, such as a wet etching or a dry etching process. The extent to which the dielectric interposers 606 are recessed (or the size of the portion removed) is determined by the processing conditions such as the duration of the dielectric interposers 606 is exposed to an etching chemical. In the depicted embodiments, the duration is controlled such that the side portions of the dielectric interposers 606 directly underlying the gate spacers 240 are removed in their entirety, while the center portions of the dielectric interposers 606 remain substantially unchanged. In other words, the remaining portions of the dielectric interposers 606 each has a sidewall that is substantially aligned with a sidewall of the dummy gate structures 210 (e.g. the sidewall in the XZ plane, defined by the X-direction and the Z-direction). As illustrated in FIG. 7E, the selective etching process creates recesses (also referred to as second gaps) 610, which extend the trenches 151 into areas beneath the semiconductor layers 220A and top spacers 240. Meanwhile, the semiconductor layers 220A are only slightly affected during the selective etching process. The etch selectivity between the first semiconductor layers 220A and the dielectric interposers 606 is made possible by the etchant and etching process. For example, the dielectric interposers 606 may be etched away at a substantially faster rate (e.g. more than about 5 times to about 10 times faster) than the first semiconductor layers 220A. In some embodiments, the etching process is wet etching with HF solution as etchant.

In some embodiments, a second wet cleaning process using a second cleaning chemical solution is applied to the workpiece 100 to remove any residues, such as metal residues after the second etching process at block 868 and prepare surfaces for the following processes. In the disclosed embodiments, the second cleaning chemical solution includes hydrofluoric acid (HF), water (H2O), and one or more pH adjuster. In some embodiments, the cleaning solution includes hydrofluoric acid (HF) with a volume concentration (volume ratio) ranging between 0.02% and 20%, water (H2O) with a volume concentration ranging between 60% and 99.8%, and one of a base pH adjuster and an acid pH adjuster. In some embodiments, the base adjuster includes ammonium hydroxide (NH4OH) with a volume concentration ranging between 0% and 20%, so to tune the pH value of the cleaning solution to a pH value ranging between 5 and 12. In some embodiments, the acid adjuster includes hydrogen chloride (HCl), phosphoric acid (H3PO4), sulfuric acid (H2SO4), or a combination thereof, with a volume concentration ranging between 0% and 20%, so to tune the pH value of the cleaning solution to a pH value ranging between 1 and 6. In furtherance of the embodiments, the cleaning solution includes a temperature ranging between 5° C. and 80° C. when it is applied to the workpiece 100.

In one embodiment, the second cleaning chemical solution includes hydrofluoric acid (HF) with a volume concentration (volume ratio) ranging between 0.02% and 20%; water (H 2°) with a volume concentration ranging between 60% and 99.8%; and a base pH adjuster NH 4OH with a volume concentration ranging between 0% and 20% to tune the pH value of the cleaning solution to a pH value ranging between 5 and 12, and furthermore with a solution temperature ranging between 5 °C and 80 °C. In another embodiment, the cleaning solution includes hydrofluoric acid (HF) with a volume concentration (volume ratio) ranging between 0.02% and 20%; water (H2O) with a volume concentration ranging between 60% and 99.8%; and an acid pH adjuster containing hydrogen chloride (HCl), phosphoric acid (H3PO4), sulfuric acid (H2SO4), or a combination thereof, with a volume concentration ranging between 0% and 20% to tune the pH value of the cleaning solution to a pH value ranging between 1 and 6, and furthermore with a solution temperature ranging between 5° C. and 80° C.

Such prepared cleaning solution has a high selectivity and effectiveness to cleaning the workpiece 100 without damages to the dielectric interposers 606 and the first semiconductor layers 220A, and without metal residues. Furthermore, the third cleaning solution, described below, is further tuned for its effectiveness. After the second etching process and the second cleaning process, the second gaps 610 are formed between the first semiconductor layers 220A. Especially, the experiment date found that the first semiconductor layers 220A have no or minimal loss at the edges. The first semiconductor layers 220A keep the profile without rounding issue. In some embodiments, the recessed sidewalls 616 of the dielectric interposers 606 have concaved surfaces. In this case, each gap 610 between adjacent first semiconductor layers 220A has varying recessing dimensions along the Z direction from the underlying first semiconductor layer 220A to the overlying first semiconductor layer 220A. the maximum recessing dimension is at middle level between the underlying and overlying first semiconductor layers 220A.

Referring to block 870 of FIG. 1B and FIG. 7F, inner spacers (or second spacers) are formed in the second gaps 610. The inner spacers include one or more dielectric material and are directly underlying the top spacers 240. The inner spacers may be formed by any suitable procedure, such as a procedure that includes deposition and etching and may further include cleaning.

Referring to FIG. 7F, a dielectric material 250 is formed to fill in the second gaps 610. The method to form the dielectric material 250 includes deposition using suitable deposition technologies, such as CVD, PVD, PECVD, MOCVD, ALD, PEALD, or combinations thereof. The dielectric material 250 is different from the composition of the dielectric interposers 606 to achieve etch selectivity during subsequent processes, such as during the channel-release operation. In some embodiments, the dielectric material may be selected from SiON, SiOC, SiOCN, other suitable dielectric material or combinations thereof. In some embodiments, the proper selection of the dielectric material may be based on its dielectric constant. In an embodiment, the dielectric material 250 may have a dielectric constant lower than that of the top spacers 240. In some other embodiments, this dielectric material 250 may have a dielectric constant higher than that of the top spacers 240. This aspect of the dielectric material will be further discussed later.

Still referring to FIG. 7F, an etching process (also referred to as a third etching process) is applied to the dielectric material 250 such that the dielectric material 250 formed on sidewalls of the trenches 151 is removed by the third etching process. The third etching process includes an anisotropic etch with substantially vertical etching so that the portions of the dielectric material 250 deposited on the sidewalls and bottom surface of the trenches 151 are removed. In the depicted embodiment, the third etching process is a self-aligned anisotropic dry-etching process, such that the top spacers 240 are used as the masking element. Alternatively, a different masking element (e.g. a photoresist) may be used. The third etching process removes the dielectric materials 250 within the trenches 151 but does not substantially affect the dielectric material 250 within the second gaps 610. As a result, the dielectric material 250 filling in the second gaps 610 become inner spacers (or second spacers), being referred to with the numeral 250 as well. In other words, the inner spacers 250 are formed in the second gaps 610 between vertically adjacent (e.g. along in the Z-direction) side portions of the first semiconductor layers 220A.

In the disclosed embodiment, after the third etching process, a third wet cleaning process using a third cleaning chemical solution is applied to the workpiece 100 to remove any residues, such as metal residues from the third etching process, and prepare the surfaces for the following processes. In the disclosed embodiments, the third cleaning chemical solution includes hydrofluoric acid (HF), water (H2O), and one or more pH adjuster. In some embodiments, the cleaning solution includes hydrofluoric acid (HF) with a volume concentration (volume ratio) ranging between 0.02% and 20%, water (H2O) with a volume concentration ranging between 60% and 99.8%, and one of a base pH adjuster and an acid pH adjuster. In some embodiments, the base adjuster includes ammonium hydroxide (NH4OH) with a volume concentration ranging between 0% and 20%, so to tune the pH value of the cleaning solution to a pH value ranging between 5 and 12. In some embodiments, the acid adjuster includes hydrogen chloride (HCl), phosphoric acid (H3PO4), sulfuric acid (H2SO4), or a combination thereof, with a volume concentration ranging between 0% and 20%, so to tune the pH value of the cleaning solution to a pH value ranging between 1 and 6. In furtherance of the embodiments, the cleaning solution includes a temperature ranging between 5° C. and 80° C. when it is applied to the workpiece 100. In one embodiment, the third cleaning chemical solution includes hydrofluoric acid (HF) with a volume concentration (volume ratio) ranging between 0.02% and 20%; water (H2O) with a volume concentration ranging between 60% and 99.8%; and a base pH adjuster NH4OH with a volume concentration ranging between 0% and 20% to tune the pH value of the cleaning solution to a pH value ranging between 5 and 12, and furthermore with a solution temperature ranging between 5° C. and 80° C. In another embodiment, the cleaning solution includes hydrofluoric acid (HF) with a volume concentration (volume ratio) ranging between 0.02% and 20%; water (H2O) with a volume concentration ranging between 60% and 99.8%; and an acid pH adjuster containing hydrogen chloride (HCl), phosphoric acid (H3PO4), sulfuric acid (H2SO4), or a combination thereof, with a volume concentration ranging between 0% and 20% to tune the pH value of the cleaning solution to a pH value ranging between 1 and 6, and furthermore with a solution temperature ranging between 5° C. and 80° C.

In some embodiments, the first trenches 151 are further extended below the bottommost of the semiconductor layer 220A as illustrated in FIG. 7G. FIG. 7G is a sectional view of the device structure 100 along the Y direction, in portion, constructed according to some embodiments. FIG. 7G is similar to FIG. 7F but the first trenches 152 are vertically extending into the semiconductor substrate 200. This may be formed by the etching process of the operation 850 with extended etching duration such that the first trenches 151 are further recessed below the bottommost of the semiconductor layer 220A, or in alternative embodiments, are recessed below the bottommost of the semiconductor layer 220A collectively by the etching process at operation 850 and various subsequent etching processes in the blocks 860, 864, 868 and 870. In some embodiments, the first trenches 151 are recessed below the top surface of the isolation structure 203, as illustrated in FIG. 7H. FIG. 7H is a sectional view of the device structure 100 along DD′ of FIG. 6A, in portion or entirety, constructed according to some embodiments. Note that spacers 240 are also formed on the sidewalls of the fins 130a and 130b and when the first trenches 151 are formed in the source/drain regions, spacers 240 remain or partially remain.

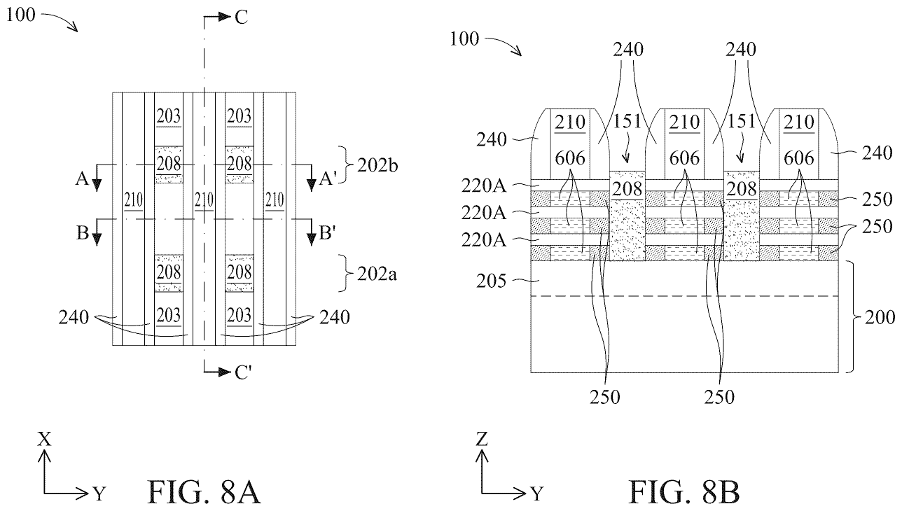

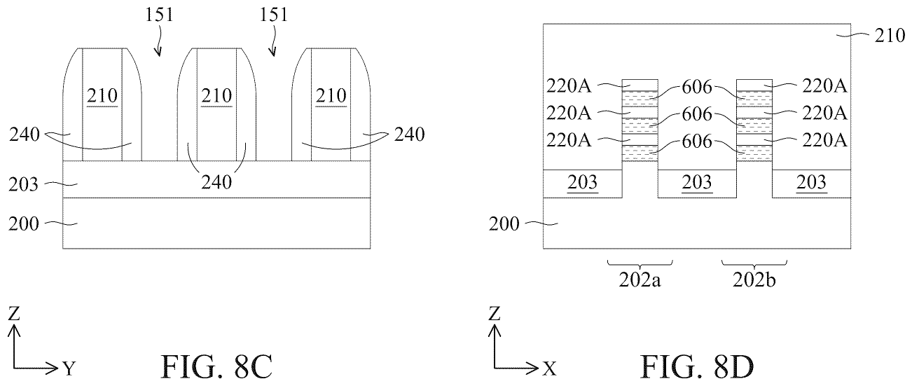

Referring to block 872 of FIG. 1B and FIGS. 8A-8D, the method 800 continues to form epitaxial source/drain features 208 in trenches 151. In some embodiments, one source/drain feature is a source electrode, and the other source/drain feature is a drain electrode. The semiconductor layers 220A that extend from one source/drain feature 208 to the other source/drain feature 208 may form channels of the device structure 100. The epitaxial source/drain features 208 may include any suitable semiconductor materials. For example, the epitaxial source/drain features 208 in an n-type GAA device may include Si, SiC, SiP, SiAs, SiPC, or combinations thereof; while the epitaxial source/drain features 208 in a p-type GAA device may include Si, SiGe, Ge, SiGeC, or combinations thereof. The source/drain features 208 may be doped in-situ or ex-situ. For example, the epitaxially grown Si source/drain features may be doped with carbon to form silicon: carbon (Si:C) source/drain features, phosphorous to form silicon: phosphor (Si:P) source/drain features, or both carbon and phosphorous to form silicon carbon phosphor (SiCP) source/drain features; and the epitaxially grown SiGe source/drain features may be doped with boron. Various annealing processes are performed to activate the dopants in the epitaxial source/drain features 208, reduce channel resistance and source/drain resistance, reduce the channel length variation and improve the device performance.

The epitaxial source/drain features 208 directly interface with the continuous sidewall surfaces of the first semiconductor layers 220A. During the epitaxial growth, semiconductor materials grow from the exposed top surface of the substrate 200 (e.g. the exposed top surface of doped region 205) as well as from the exposed side surfaces of the semiconductor layers 220A. It is noted that semiconductor materials do not grow from the surfaces of the inner spacers 250 and the top spacers 240 during the epitaxial growth process.

The epitaxial source/drain features 208 directly interface with the continuous sidewall surfaces of the first semiconductor layers 220A. During the epitaxial growth, semiconductor materials grow from the exposed top surface 200a of the substrate 200 (e.g. the exposed top surface of doped region 205) as well as from the exposed side surfaces of the semiconductor layers 220A. It is noted that semiconductor materials do not grow from the surfaces of the inner spacers 250 and the top spacers 240 during the epitaxial growth process. In the present embodiment, the semiconductor layers 220A are undoped silicon or alternatively undoped silicon germanium. However, dopants from the source/drain features 208 may diffuse into semiconductor layers 220A and reduce the lengths of the semiconductor layers 220A. Furthermore, the diffusion may not be uniform among vertically stacked semiconductor layers 220A, resulting in uneven channel lengths and degradation of the GAA device performance. In the disclosed embodiments, the method to form the source/drain features 208 is designed to reduce this nonuniformity and enhance the device performance. The S/D features 208 includes a first S/D feature 208a and a second S/D feature 208b with opposite dopant types, which will be further described below in detail.

The method 872 to form the source/drain features 208 is further described below in detail with reference to FIG. 1C and FIGS. 7I-7R. FIGS. 7I-7R are sectional views of the device structure 100 along DD′ of FIG. 6A at various fabrication stages constructed according to some embodiments. The method 872 to form the source/drain (S/D) features 208 includes multiple operations and especially includes two different annealing operations with a first one before and a second one after ion implantation.

Referring to block 874 of FIG. 1C and FIG. 7I, semiconductor features 252 are formed on the bottom portions of the trenches 151 according to some embodiments. The semiconductor features 252 are undoped silicon formed by selective epitaxial growth. The semiconductor features 252, as undoped silicon, can provide isolation and avoid short to adjacent active regions.

Referring to block 876 of FIG. 1C and FIG. 7I, bottom isolation features 254 are formed on the bottom portions of the trenches 151 according to some embodiments. The bottom isolation features 254 are dielectric features to provide isolation of the source/drain features from the substrate 200 and other conductive features, such as backside contacts. In some embodiments, the bottom isolation features 254 include silicon oxide, other suitable dielectric material (such as silicon oxynitride) or a combination thereof. In the present embodiment, the bottom isolation features 254 are formed on the semiconductor features 252. The bottom isolation features 254 and the semiconductor features 252 collectively provide an effective isolation function.

In some embodiments, the bottom isolation features 254 are formed by a method that includes deposition of one or more dielectric material to the semiconductor features 252, thereby filling the dielectric material in the trenches 151; performing a CMP process to the dielectric material; and etching to recess the dielectric material. In other embodiments, the bottom isolation features 254 are formed by a bottom-up deposition process such that the dielectric material is only deposited on the bottom surface of the trenches 151, such as on the semiconductor features 252. In yet other embodiments, the bottom isolation features 254 are formed by a method that includes deposition of the dielectric material; performing a plasma treatment to the deposited dielectric material such that the portion of the deposited dielectric material on the sidewalls of the trenches 151 is selectively treated, resulting in with different composition and/or different structure; and performing an etching process to selectively removed the treated portion of the dielectric material so that only bottom portion of the deposited dielectric material remains on the semiconductor features 252. In furtherance of the embodiments, the plasma treatment includes a tilted plasma treatment with an angle so that only desired top portion of the dielectric material is treated. In some examples, the plasma treatment includes a plasma of proper species, such as oxygen plasma so that the treated dielectric material converts to silicon oxynitride while untreated dielectric material remains as silicon nitride.

Referring to block 877 of FIG. 1C and FIG. 7J, a hard mask 256 is formed on the semiconductor structure 100. The hard mask 256 covers second active region 202b and includes an opening to expose first active region 202a. In some embodiments, first active region 202a is designed such that a p-type FET (pFET) is to be formed therein while second active region 202b is designed such that a n-type FET (nFET) is to be formed therein. Therefore, the hard mask 256 is also referred to as a block layer 256. The hard mask 256 includes one or more dielectric material, such as silicon nitride, silicon oxide, silicon oxynitride, other suitable dielectric material or a combination thereof. In some embodiments, the hard mask 256 is designed to have a different composition from that of the isolation structure 203. The hard mask 256 is formed by any suitable method. In some embodiments, the hard mask 256 is formed by a procedure that includes a deposition process and a patterning process. The patterning process further includes a photolithography process and etching.

Referring to block 878 of FIG. 1C and FIG. 7K, performing an epitaxial growth to form a source/drain (S/D) feature 208a in the trench(es) 151 within first active region 202a, specifically in a subset of the trench(es) 151 within the first active region 202a. In some embodiments, the S/D feature 208a is only formed on first active region 202a while second active region is protected from epitaxial growth since it is covered by the dielectric material of the bottom isolation feature 254. In the disclosed embodiments, the S/D feature 208a is formed on the bottom isolation feature 254. The S/D feature 208a is epitaxially grown from semiconductor surfaces, such as exposed sidewalls of the semiconductor layers 220A within the trench(es) 151. In the present embodiments, the S/D feature 208a is semiconductor feature that includes silicon, silicon germanium, other suitable semiconductor material or a combination thereof. The S/D feature 208a is further doped with a p-type dopant, such as boron, by an in-situ process during the epitaxial growth. In furtherance of the embodiment, the epitaxial growth includes applying a precursor that includes a semiconductor-containing chemical and a dopant-containing chemical such that the S/D feature 208a is in-situ doped during the epitaxial growth. However, the in-situ doping may not reach the desired doping concentration if the doping dosage is too low or have out-diffusion issue if the doping dosage is too high, which will be addressed by the disclosed method as illustrated in various operations described below. The in-situ doping concentration is a first doping concentration Cp1, which is less than a second doping concentration Cp2, which will be described later.

Referring to block 880 of FIG. 1C and FIG. 7K, performing a first annealing process to the workpiece 100, especially to the S/D feature 208a while the second active region 202b is covered by the hard mask 256. Particularly, the first annealing process is a laser annealing and includes a laser spike anneal (LSA). The LSA process is a thermal annealing process employing laser energy for thermal annealing effect. In an LAS process, a laser delivers transient, spatially localized heat to a semiconductor structure to achieve various thermal effects such as dopant activation, defect repair, phase transformation, stress relaxation, or contact/silicide formation, while constraining diffusion and limiting the overall thermal budget. Unless stated otherwise, numerical values are approximate and may vary by ±10%. LSA couples optical energy into surface and near-surface regions of a substrate (such as a wafer). The absorbed energy produces a short-duration temperature excursion with a rapid rise (>10⁶° C./s), a brief dwell, and a rapid quench (>10⁵° C./s). The thermal penetration depth is predominantly governed by optical absorption and by √(α·τ), where α is thermal diffusivity and τ is the effective heating time; thus, heating is concentrated near the top micrometers of the stack, limiting junction diffusion and protecting temperature-sensitive backend films. An LSA system may include: (i) a laser source (continuous, quasi-CW, or pulsed), (ii) beam-conditioning optics to form a line or rectangular spot with homogenized intensity, (iii) a precision wafer stage for serpentine scanning, (iv) a process chamber providing an inert or reducing ambient, and (v) in-situ metrology (multi-wavelength pyrometry, time-resolved reflectometry) for closed-loop temperature control. Other elements may include a preheat station (e.g., 150-500 °C), backside absorbers or roughening to stabilize emissivity, and top anti-reflection/energy-coupling layers. In various embodiments, an LSA includes an laser energy with wavelength ranging between about 193 nm and 1064 nm (the selection being based on stack optical constants and target absorption depth); a pulse width / effective dwell ranging between about 0.1 μs and 10 ms (including quasi-CW exposures created by scanned overlap); a peak surface temperature (Si) ranging between about 900° C. and 1350° C. (typically below the silicon melting point to avoid melt); an ambient gas such as N₂, Ar, He, or forming gas from sub-Torr to near-atmospheric pressure; a beam geometry such as line length ranging between about 5 mm and 50 mm, a beam width ranging between about 100 μm and 1000 μm with ≤5% within-line non-uniformity; a scan speed/overlap ranging between about 50 mm/s and 2000 mm/s with ~50-95% overlap to tune effective dwell and uniformity; and a temperature control such as emissivity-corrected pyrometry with feedback and/or optional reflectometry endpoints.

One example of the LSA process is applied by an LSA system, such as one developed by Ultratech. In some embodiments, the LSA system includes carbon oxide (CO₂) gas used to generate laser with a wavelength at about 10.6 micrometer. In some embodiments, the LSA process is implemented in nitrogen (N₂) environment with an annealing temperature ranging from 800° C. to 1300° C., with an atmosphere pressure, and with a dwell time ranging between 0.2 ms (milliseconds) and 1 ms. The first annealing process is implemented before the first ion implantation process (to be described below in block 882 of FIG. 1C) and is designed to prepare the first S/D feature 208a for the first ion implantation process to achieve the desired result. The S/D feature 208a is in-situ doped at block 878 and is further ion-implanted at block 882 to increase the dopant concentration because dopant concentration by the in-situ doping is not high enough. However, the dopants of the S/D feature 208a will diffuse into semiconductor layers 220A and reduce the lengths of semiconductor layers 220A and reduce the effective channel length (which is referred to as doping proximity), thereby reduce the channel resistance and reduce threshold voltage. Furthermore, the diffusion is not uniform among vertically stacked semiconductor layers 220A, resulting in uneven channel lengths and degradation of the GAA FET device performance. For example, top channel has a more reduced doping proximity and more reduction of the channel length, leading to the variation of the effective channel lengths (Lc) from the top channel to the bottom channel (top channel has shorter Lc and the bottom channel has a longer Lc). The annealing process at block 880 can reduce the defects of the S/D feature 208a and drive the dopants deeper and improve the uniformity of the dopants in semiconductor layers 220A. In other aspects, the annealing process needs a temperature to be higher enough to effectively reduce the defects of the S/D feature 208a and short enough to control the thermal effect of the annealing process within the thermal budget. Accordingly, the annealing process is designed using the described LSA technique and the aforementioned ranges of annealing temperature and duration, taking into account the above analysis, process conditions, and supporting experimental results.

In some embodiments, the laser annealing is performed using a pulsed laser with a repetition rate ranging between about 1 kHz and about 10 MHz. In some embodiments, when the laser beam generated from the LSA system is directed to the surface of a semiconductor substrate, the incident angle is at about the Brewster angle (~72 degree, for example), such that the polarization direction of the laser is substantially parallel to the surface of the semiconductor substrate. In some embodiments, a hard mask is formed to cover the first S/D feature 208a before the first annealing process to prevent the dopants from out-diffusion. Furthermore, the hard mask may serve as a screen layer for the subsequent ion implantation to prevent from the tunneling effect.

Referring to block 882 of FIG. 1C and FIG. 7K, performing a first ion implantation process to the first S/D feature 208a while the second active region 202b is covered by the hard mask 256. The first ion implantation process introduces p-type dopants, such as boron, into the first S/D feature 208a with a second doping concentration Cp2 greater than the first doping concentration Cp1. In some embodiments, the first ion implantation process is applied with a kinetic ion energy ranging between 1 keV and 55 keV and with a dosage ranging between 2*10¹³ atoms/cm² and 6*10¹⁵ atoms/cm². The first ion implantation process is designed to introduce higher concentration dopants to the first S/D feature 208a. However, the dopants introduced into the first S/D feature 208a diffuses in the first S/D feature 208a, and further laterally diffuses into the semiconductor layers (or channel layers) 220A. The experiments and analysis found and identified that the vertical diffusion in the S/D feature 208a is impacted by the defects in the S/D feature 208a, resulting in nonuniform distribution of the dopants in the S/D feature 208a. This further impacts the diffusion of the dopants into the channel layers, reducing the length of the channel layers unevenly and leading to the degradation of performance of the GAA device. The disclosed method is designed to address the issues/especially, the first LSA process at block 880 effectively reduces the defects in the S/D feature 208a without substantially increasing the thermal budget.

Referring to block 884 of FIG. 1C and FIG. 7K, performing a second annealing process to the device structure 100, especially to the S/D feature 208a. Particularly, the second annealing process is different from the first annealing process and is designed to activate dopants, repair surface damage, and modify material properties and recrystallize implant induced amorphous structure of the S/D feature 208a after the ion implantation. The first annealing process is implemented with a first gas, a first annealing temperature and a first annealing duration while the second annealing process is implemented with a second gas, a second annealing temperature and a second annealing duration different from the first gas, the first annealing temperature and the first annealing duration, respectively. The first and second gases refer to the chemical environment of the device structure 100 during the corresponding annealing process. In the disclosed embodiments, the second annealing temperature is less than the first annealing temperature; and the second annealing duration is greater than the first annealing duration. In some embodiments, the second gas includes O2, H2 or a combination thereof and while the first gas includes argon.

In the disclosed embodiment, the second annealing process includes rapid thermal annealing (RTA). The RTA process is implemented with an annealing temperature less than the annealing temperature of the first annealing process and an annealing duration greater than the annealing duration of the first annealing process. In some embodiments, the RTA process is implemented in an environment of nitrogen (N₂), oxygen (O₂), hydrogen (H₂), NH₃, Helium (He) or a combination thereof. In some embodiments, the RTA process is implemented with an annealing temperature ranging from 500° C. to 1200° C., with a pressure ranging between 1 Torr and 760 Torr, and with a dwell time ranging between 1 s (second) and 60 s. In some embodiments, the second annealing process is deferred and is collectively implemented after the formation of the second S/D feature 208b. In the disclosed embodiments, an annealing duration of an annealing process refers to a dwell time; and an annealing temperature of the annealing process refers to a peak temperature through the corresponding annealing process.

Referring to block 886 of FIG. 1C and FIG. 7L, the hard mask 256 is removed by a suitable etching process, such as wet etching, dry etching, other suitable etching or a combination thereof.

Referring to block 887 of FIG. 1C and FIG. 7L, a second hard mask 258 is formed on the device structure 100. The hard mask 258 covers first active region 202a and includes an opening to expose second active region 202b. In the disclosed embodiment, the first active region 202a is designed for a pFET to be formed therein while the second active region 202b is designed for a nFET to be formed therein. The hard mask 258 includes one or more dielectric material, such as silicon nitride, silicon oxide, silicon carbonitride, silicon oxynitride, other suitable dielectric material or a combination thereof. In some embodiments, the hard mask 258 is designed to have a different composition from that of the isolation structure 203. The hard mask 258 is formed by any suitable method. In some embodiments, the hard mask 258 is formed by a procedure that includes a deposition process and a patterning process. The patterning process further includes a photolithography process and etching.

Referring to block 888 of FIG. 1C and FIG. 7M, performing an epitaxial growth to form a second source/drain (S/D) feature 208b in the trench(es) 151 within second active region 202b, specifically in a subset of the trench(es) 151 within the second active region 202b. In some embodiments, the source/drain (S/D) feature 208b is only formed on second active region 202b while first active region 202a and the first S/D feature 208a, is protected from epitaxial growth since it is covered by the dielectric material of the hard mask 258. In the disclosed embodiments, the S/D feature 208b is formed on the bottom isolation feature 254. The S/D feature 208b is epitaxially grown from semiconductor surfaces, such as exposed sidewalls of the semiconductor layers 220A within the trench(es) 151. In the present embodiments, the S/D feature 208b is semiconductor feature that includes silicon, silicon germanium, other suitable semiconductor material or a combination thereof. The S/D feature 208b is further doped with an n-type dopant, such as phosphorous, by an in-situ process during the epitaxial growth. In furtherance of the embodiment, the epitaxial growth includes applying a precursor that includes a semiconductor-containing chemical and a dopant-containing chemical such that the S/D feature 208b is in-situ doped during the epitaxial growth. However, the in-situ doping may not reach the desired doping concentration if the doping dosage is too low or have out-diffusion issue if the doping dosage is too high, which is addressed by the disclosed method as illustrated in various operations described below. The in-situ doping concentration is a first doping concentration Cn1, which is less than a second doping concentration Cn2 by ion implantation, which will be described later.

Referring to block 890 of FIG. 1C and FIG. 7N, another second hard mask 260 is formed on the device structure 100. The hard mask 260 covers both the first S/D feature 208a and the second S/D feature 208b. The hard mask 260 includes one or more dielectric material, such as silicon nitride, silicon oxide, silicon carbonitride, silicon oxynitride, other suitable dielectric material or a combination thereof. The hard mask 260 is formed by any suitable method. In some embodiments, the hard mask 260 is formed by a procedure that includes a deposition process and a patterning process. The patterning process further includes a photolithography process and etching. The hard mask 260 serves as a dielectric layer to prevent the dopant from out-diffusion during the subsequent annealing process and may further serve as a screen layer during the subsequent implantation process. Therefore, the hard mask 260 is also referred to as a block layer 260. The operation 890 may further include removing the hard mask 258, before forming the hard mask 260, by a suitable etching process, such as wet etching, dry etching, other suitable etching or a combination thereof. In some embodiments, the hard mask 258 remains and the hard mask 260 is formed on the hard mask 258 to have a collective hard mask (also referred to by the numeral 260) that has a first thickness on the first S/D feature 208a and a second thickness on the second S/D feature 208b. The first thickness is greater than the second thickness. The first thickness is thick enough to prevent the first S/D feature 208a from introducing dopants during the subsequent ion implantation. The second thickness is thin enough without blocking the dopant during the subsequent ion implantation but thick enough to function as a screen layer to prevent the tunneling effect during the subsequent ion implantation.

In yet another embodiment, the hard mask 258 is removed and the hard mask 260 is formed to cover both the first S/D features 208a and the second S/D features 208b. Another hard mask 262 is formed to cover the first S/D feature 208a and is absent from the second S/D feature 208b, as illustrated in FIG. 7O. Thus, the hard masks 260 and 262 constitute a collective hard mask with different thicknesses with respective functions of blocking ion implantation and ion implantation screening.

Referring to block 892 of FIG. 1C and FIG. 7N, performing a first annealing process to the second S/D feature 208b. Particularly, the first annealing process includes a laser spike anneal (LSA). The LSA process is a thermal annealing process employing laser energy for thermal annealing effect. In some embodiments, the LSA system includes carbon oxide (CO₂) gas used to generate laser with a wavelength at about 10.6 micrometer. In some embodiments, the LSA process is implemented in nitrogen (N₂) environment with an annealing temperature ranging from 800° C. to 1300° C., with an atmosphere pressure, and with a dwell time ranging between 0.2 ms and 1 ms.

Referring to block 894 of FIG. 1C and FIG. 7N, performing a second ion implantation process to the second S/D feature 208b. In some embodiments, the second ion implantation process is implemented after the formation of the hard mask 262. The second ion implantation process introduces n-type dopants, such as phosphorous, into the second S/D feature 208b with a second doping concentration Cn2 greater than the first doping concentration Cn1. In some embodiments, the second ion implantation process is applied with a kinetic ion energy ranging between 1 keV and 55 keV and with a dosage ranging between 2*10¹³ atoms/cm² and 6*10¹⁵ atoms/cm². The second ion implantation process is designed to introduce higher concentration dopants to the second S/D feature 208b. However, the dopants introduced into the second S/D feature 208b will diffuse inside the second S/D feature 208b and further laterally diffuse into the semiconductor layers (or channel layers) 220A. As noted above, the experiments and analysis found and identified that the vertical diffusion in the S/D feature 208b is impacted by the defects in the S/D feature 208b, resulting in nonuniform distribution of the dopants in the S/D feature 208b. This further impacts the diffusion of the dopants into the channel layers, reducing the length of the channel layers unevenly and leading to the degradation of performance of the GAA device. The disclosed method is designed to address the issues/ especially, the LSA process at block 892 effectively reduces the defects in the S/D feature 208b and eliminate or reduce the degradation of the GAA device.

Referring to block 896 of FIG. 1C and FIG. 7N (or FIG. 7O), performing a second annealing process to the second S/D feature 208b. Particularly, the second annealing process is different from the first annealing process and is designed to activate dopants, repair surface damage, and modify material properties and recrystallize implant induced amorphous structure of the S/D feature 208b after the ion implantation. In the disclosed embodiment, the second annealing process includes rapid thermal annealing (RTA). The RTA process is implemented with an annealing temperature less than the annealing temperature of the first annealing process. In some embodiments, the RTA process is implemented in an environment of nitrogen (N₂), oxygen (O₂), hydrogen (H₂), NH₃, Helium (He) or a combination thereof. In some embodiments, the RTA process is implemented with an annealing temperature ranging from 500° C. to 1200° C., with a pressure ranging between 1 Torr and 760 Torr, and with a dwell time ranging between 1 s (second) and 60 s.

The method 872 may further include other operations. In some embodiments, the hard mask or the collective hard mask 260 may be removed after the implementation of the operations at block 896. In some embodiments, the hard mask 260 remains as a contact etch stop layer during the subsequent processes to form an interlayer dielectric layer and contacts on the S/D features 208. In some embodiments, the procedure to form the first S/D feature 208a and the second S/D feature 208b may be implemented in different sequence such that the second S/D feature 208b is formed and thereafter the first S/D feature is formed. In some embodiments, the LSA process to the first S/D feature 208a at block 888 may be skipped and the RTA process at block 884 is skipped as well while the RTA process at block 896 will serve as a collective RTA process to both first S/D features 208a and the second S/D features 208b.

By implementing method 800, especially various operations in method 872, the device structure 100 made thereby is improved, and device quality and performance are enhanced as illustrated in FIGS. 7P, 7Q and 7R. FIG. 7P is a sectional view of the device structure 100 along AA′ of FIG. 8A, in portion, such as portion in the dashed box 264 of FIG. 8B, constructed according to some embodiments. Note that FIGS. 8A-8D and FIG. 7P may illustrate different numbers of channel layers. For example, FIG. 7P illustrates 3 channel layers 220A. FIG. 7Q is a bar diagram illustrating the doping amounts of channel layers 220A constructed according to some embodiments. FIG. 7R is a diagram illustrating the doping concentration of channel layers 220A constructed according to some embodiments.

In FIG. 7P, the S/D feature 208b is the S/D feature with n-type dopants and may include multiple epitaxial grown semiconductor layers with respective doping concentrations. In the disclosed embodiment, the S/D feature 208b includes a first semiconductor layer L1 and a second semiconductor layer L2. In furtherance of the embodiments, the first semiconductor layer L1 includes silicon doped with arsenic (Si:As) and the second semiconductor layer L2 includes silicon doped with phosphorous (Si:P). The first semiconductor layer L1 epitaxially grows from the sidewall surfaces of the channel layers 220A; and the second semiconductor layer L2 epitaxially grows the first semiconductor layer L1. In the present embodiment, the dopants in the first semiconductor layer L1 choose arsenic to effectively constrain the diffusion since arsenic atom is greater than phosphorous in size and mass. In some embodiments, the epitaxial growth process is a selective epitaxial growth, and the epitaxial growth only selectively grows from semiconductor surface. In the disclosed embodiments, the first semiconductor layer L1 epitaxially grows from the exposed sidewalls of the semiconductor layers 220A, and form semiconductor islands (also referred to L1) adjacent the semiconductor layer 220A. The semiconductor layer L2 epitaxially grows from the semiconductor islands L1, merges together. The semiconductor islands L1 are vertically distanced from each other and separated by the semiconductor layer L2.

In some embodiments, the first epitaxial semiconductor layer L1 includes silicon doped with arsenic (Si:As), with a first doping concentration for an nFET. In some embodiments, the first doping concentration is less than or equal to 2*10²⁰ (at %), which is atomic percentage. In furtherance of the embodiments, the first doping concentration ranges between 0.5*10²⁰ (at %) and 2*10²⁰ (at %). In some embodiments, the precursor for the first epitaxial semiconductor layer L1 of Si: As includes silicon-containing gas (such as silane-SiH) and arsenic-containing gas (such as AsH₃).

In some embodiments, the second epitaxial semiconductor layer L2 includes silicon doped with phosphorous (Si:P) for an nFET. However, the second epitaxial semiconductor layer has a second doping concentration greater than the first doping concentration of the first epitaxial semiconductor layer. In some embodiments, the second doping concentration is greater than or equal to 0.5*10²¹ (at %). In furtherance of the embodiments, the second doping concentration ranges between 0.5*10²¹ (at %) and 2*10²¹ (at %). In some embodiments, the precursor for the second epitaxial semiconductor layer L2 of Si:P includes silicon-containing gas (such as silane-SiH) and phosphorous-containing gas (such as PH₃). In other embodiments, the deposition chemical in the precursor may include dichlorosilane (SiH₂Cl₂) for growing silicon.

In FIG. 7Q, the horizontal axis represents a dopant amount (with unit at/cm²) diffused into the channel layers 220A and the vertical axis represents a first channel layer (1^{st}), a second channel layer (2^{nd}) and a third channel layer (3^{rd}). Each channel layer 220A has a doping profile 263 as illustrated by a curve 263 in FIG. 7P, which gradually decreases to zero along Y direction from the interface between the S/D feature 208b and the channel layers 220A. As an example, the dopant amounts for each channel layer 220A (1^{st}, 2^{nd} and 3^{rd} channel layers) along the dashed line 265 of FIG. 7P are illustrated in FIG. 7Q. Especially, a diagram bar 266 represents the dopant amount at location 265 of the corresponding channel layer 220A without using the disclosed method and a diagram bar 268 represents the dopant amount at the location 265 of the corresponding channel layer 220A formed by the disclosed method 800 (including the method 872). From the bar diagram in FIG. 7Q, the dopant amounts 266 among the 1^{st}, 2^{nd} and 3^{rd} channel layers 220A are significantly different; and the dopant amounts 268 among the 1^{st}, 2^{nd} and 3^{rd} channel layers 220A are substantially uniform. Particularly, dopant amounts increase with the disclosed method compared with dopant amounts without using the disclosed method. The dopant amount of a lower channel layer 220A (such as 3^{rd} channel layer) increases more than the dopant amount of a higher channel layer 220A (such as 1^{st} channel layer). For example, the dopant amount of the 1^{st} channel layer 220A formed by the disclosed method is 1.2 times greater than the dopant amount of the 1^{st} channel layer 220A formed by an existing method; the dopant amount of the 2^{nd} channel layer 220A formed by the disclosed method is 2.3 times greater than the dopant amount of the 2^{nd} channel layer 220A formed by an existing method; and the dopant amount of the 3^{rd} channel layer 220A formed by the disclosed method is 2.3 times greater than the dopant amount of the 3^{rd} channel layer 220A formed by an existing method. This results in the GAA device structure having vertically stacked channel layers 220A with substantially equal channel length.

FIG. 7R illustrates the doping concentrations in each of the channel layers 220A along Y direction from the interface between the S/D feature 208b and the channel layers 220A. The horizontal axis represents a distance (“depth” with a unit nm) along Y direction from the interface between the S/D feature 208b and the channel layers 220A. The vertical axis represents a doping concentration (with unit at/cm³) in channel layers 220A. Especially, the diagram 400 represents results from an existing method and the diagram 402 represents results from the disclosed method. Furthermore, in diagram 400 associated with the existing method, the curve 274 represents doping concentration vs. depth of the 1^{st} channel layer 220A; and the curve 276 represents doping concentration vs. depth of the 2^{nd} or 3^{rd} channel layer 220A. In diagram 402 associated with the disclosed method, the curve 278 represents doping concentration vs. depth of the 1^{st} channel layer 220A; and the curve 280 represents doping concentration vs. depth of the 2^{nd} or 3^{rd} channel layer 220A. The locations of a same doping concentration between different channel layers 220A (such as between 1^{st} channel layer and 2^{nd}/3^{rd} channel layer) is defined by a shift dimension Δx. From FIG. 7R, it is found that Δx is greater than 1 nm for the channel layers 220A formed by the existing method and Δx is less than 1 nm for the channel layers 220A formed by the disclosed method. Overall, the GAA device formed by the disclosed method includes uniform channel length, reduced resistances, including channel resistance R_{ch} and S/D resistance Rₚ, and improved device performance.

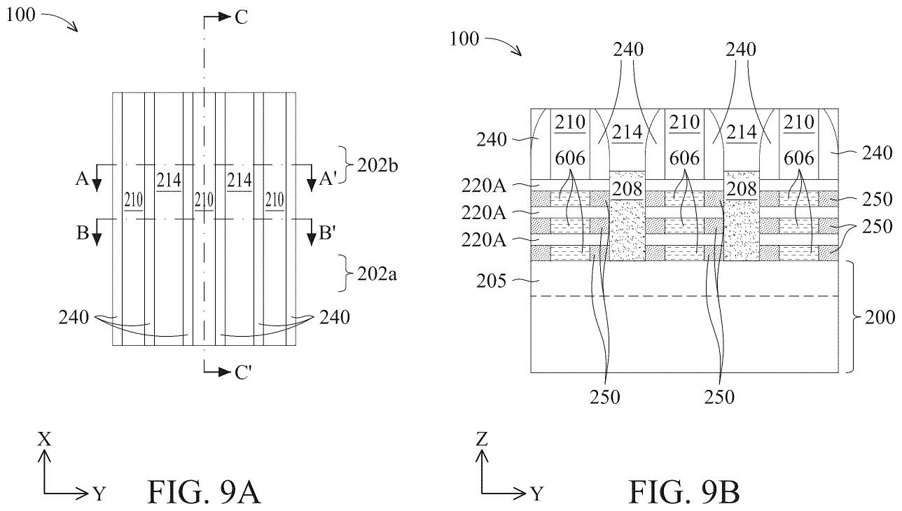

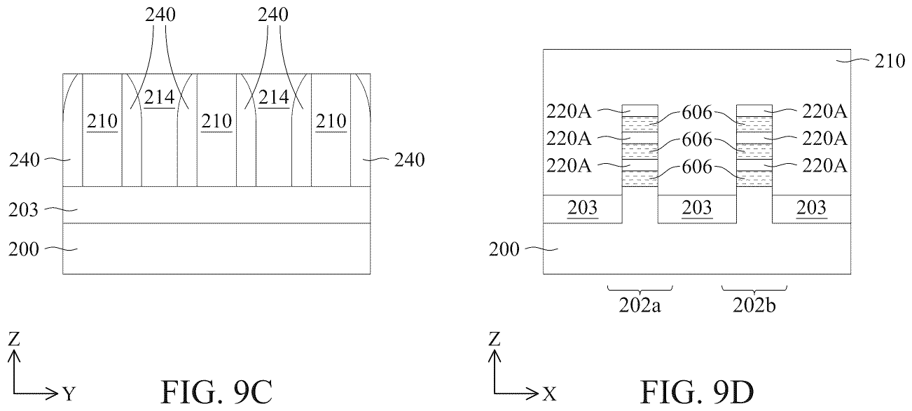

The following operations are described with references to FIG. 1D, FIGS. 9A to 16A in top views, and FIGS. 9B to 16B, 9C to 16C, and 9D to 16D in sectional views constructed according to various embodiments. After the method 872, the S/D features 208, including p-type S/D features 208a and n-type S/D features 208b, are formed. In some embodiments, the contact etch-stop layer may be also formed as illustrated in FIG. 7N or 7O.

Referring to block 900 of FIG. 1D and FIGS. 9A-9D, an interlayer dielectric (ILD) layer 214 is formed over the source/drain (S/D) features 208, including S/D features 208a, 208b in the remaining spaces of the trenches 151, as well as vertically over the isolation features 203. The ILD layer 214 may also be formed in between the adjacent gate structures 210 along the Y-direction, and in between the source/drain features 208 along the X-direction. The ILD layer 214 may include a dielectric material, such as a low-k material, or an extreme low-k material. For example, the ILD layer 214 may include SiO₂, SiOC, SiON, or combinations thereof. The ILD layer 214 may include a single layer or multiple layers, and may be formed by a suitable technique, such as CVD, FCVD, and/or spin-on techniques. After forming the ILD layer 214, a CMP process may be performed to remove excessive portions of the ILD layer 214, thereby planarizing the top surface of the ILD layer 214. Among other functions, the ILD layer 214 provides electrical isolation between the various components of the device structure 100. The ILD layer 214 may include multiple dielectric layers. In some embodiments, the ILD layer 214 includes an etch stop layer (ESL, or etch stop layer (CESL)), such as the hard mask 260, conformally disposed on surfaces of the workpiece and a low-k dielectric layer disposed over the ESL, collectively illustrated in FIGS. 9A-9D.

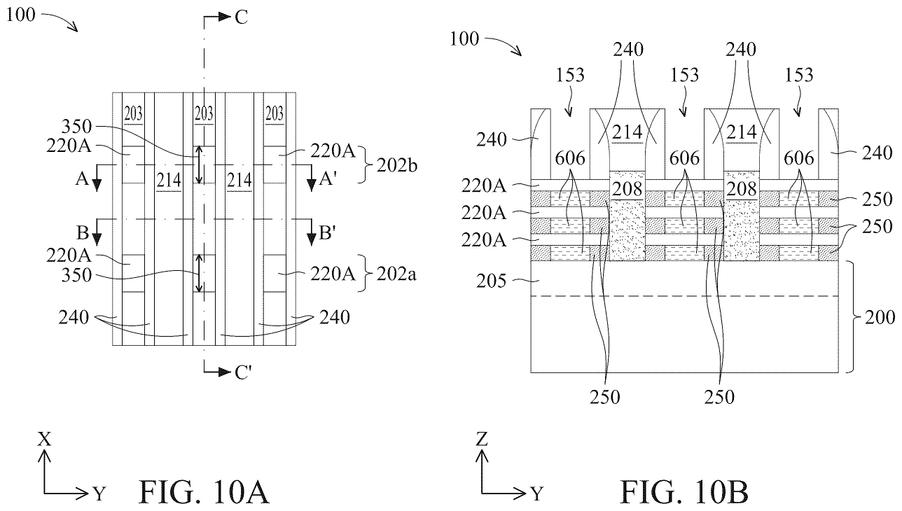

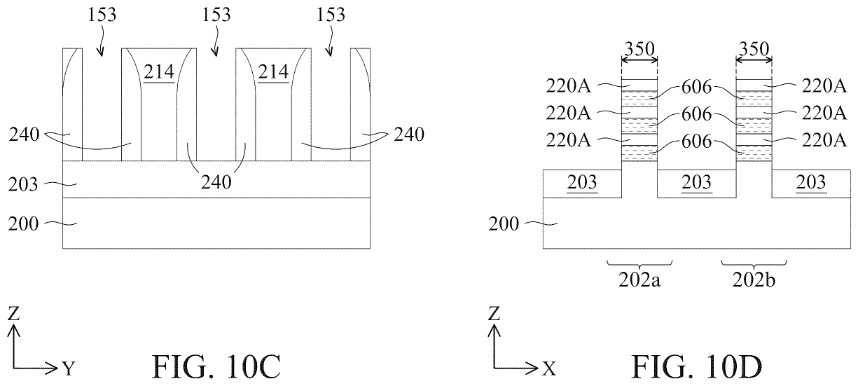

Referring to block 910 of FIG. 1C and FIGS. 10A-10D, the dummy gate structures 210 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structures 210. Then, the dummy gate structures 210 are selectively etched through the masking element. In some other embodiments, the top spacers 240 may be used as the masking element or a part thereof. For example, the dummy gate structures 210 may include polysilicon, the top spacers 240 and the inner spacers 250 may include dielectric materials, and the semiconductor layers 220A includes a semiconductor material. Therefore, an etch selectivity may be achieved by selecting appropriate etching chemicals, such that the dummy gate structures 210 may be removed without substantially affecting the features of the device structure 100. The removal of the dummy gate structures 210 creates gate trenches 153. The gate trenches 153 expose the top surfaces and the side surfaces of the first semiconductor layers 220A, and the dielectric interposers 606, as depicted in FIG. 10D. In other words, the first semiconductor layers 220A and the dielectric interposers 606 are exposed at least on two side surfaces in gate trenches 153. Additionally, gate trenches 153 also expose the top surfaces of the isolation features 203.

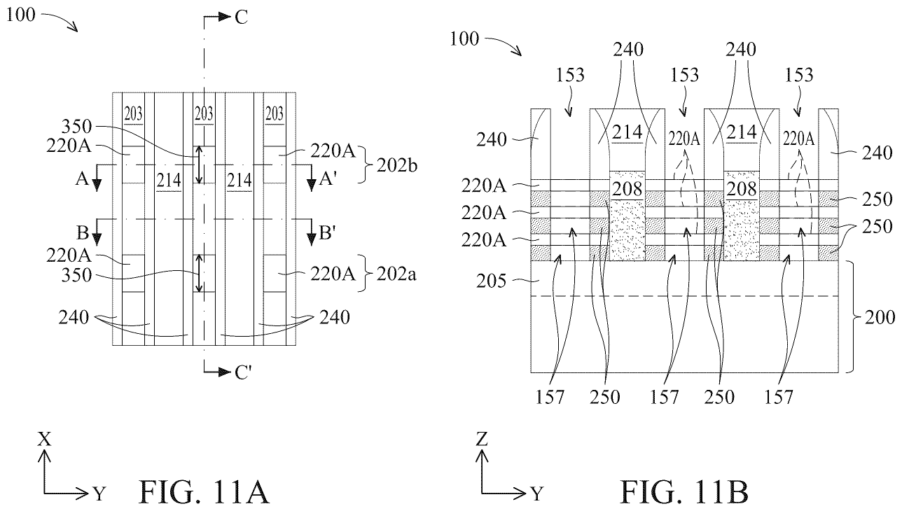

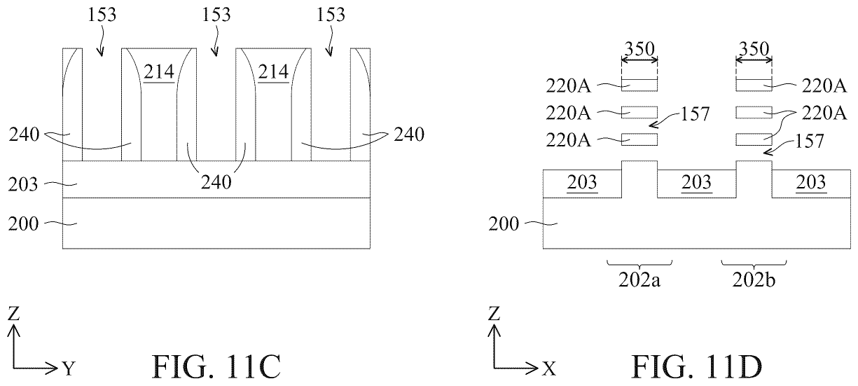

### Referring to Block 920 of FIG. 1c and FIGS. 11a-11d, the Dielectric Interposers 606

are further selectively removed through gate trenches 153, therefore releasing the first semiconductor layers 220A as channels, for example using wet or dry etching process. The etching chemical is selected such that the dielectric interposers 606 has a sufficiently different etching rate as compared to the inner spacers 250 and the first semiconductor layers 220A. As a result, the first semiconductor layers 220A and the inner spacers 250 remain substantially unchanged. This selective etching process may include one or more etching steps. The etching process may be similar to the etching process at block 868. For example, the etching process includes a wet etching step using HF solution to selectively remove the dielectric interposers 606.

As illustrated in FIGS. 11A-11D, in the present embodiment, the removal of the dielectric interposers 606 forms suspended semiconductor layers 220A and openings 157 in between the vertically adjacent layers (e.g. in the Z-direction), thereby exposing the top and bottom surfaces of the first semiconductor layers 220A. Each of the first semiconductor layers 220A are now exposed circumferentially in the X-Z plane. In addition, the portion of the doped regions 205 beneath the first semiconductor layers 220A are also exposed in openings 157. In some other embodiments however, the removal process only removes some but not all of the dielectric interposers 606.

In the examples depicted in FIGS. 10A-10D and FIGS. 11A-11D, the gate trench 153 and the opening 157 vertically adjacent to the gate trench 153 (e.g. in the Z-direction) collectively form an opening having a vertical profile. In other words, the opening collectively formed by the gate trench 153 and its corresponding opening 157 have vertical sidewalls. In some embodiments, such openings having vertical sidewalls may be formed by a plurality of etch processes. For example, the etch chemistry of the etch process used to remove the dummy gate structures 210 and thereby form the gate trenches 153 (e.g. in FIGS. 10A-10D) may include hydrogen bromide (HBr) combined with chlorine (Cl₂), tetrafluoromethane (CF₄), oxygen, or a combination thereof. Furthermore, the etch process used to selectively remove the dielectric interposers 606 and thereby form the openings 157 (e.g. in FIGS. 11A-11D) may have an initial etch chemistry including hydrogen bromide (HBr) combined with chlorine (Cl₂), oxygen, or a combination thereof. This initial etch chemistry is followed by a subsequent etch chemistry including hydrogen bromide (HBr) combined with tetrafluoromethane (CF₄), oxygen, or a combination thereof that induces the vertical profile of the opening collectively formed by the gate trench 153 and its corresponding opening 157. In an alternative embodiment, the initial etch chemistry is followed by a subsequent wet etch chemistry using HF solution to selectively remove the dielectric interposers 606. As described in further detail below, in other embodiments, however, the opening collectively formed by a gate trench 153 and its corresponding opening 157 may have a tapered profile. Such a tapered profile may be achieved by omitting the above-described subsequent etch chemistry that includes hydrogen bromide (HBr) combined with tetrafluoromethane (CF₄), oxygen, or a combination thereof. In such examples, a gate structure that is subsequently formed in the tapered opening has a tapered profile as well.

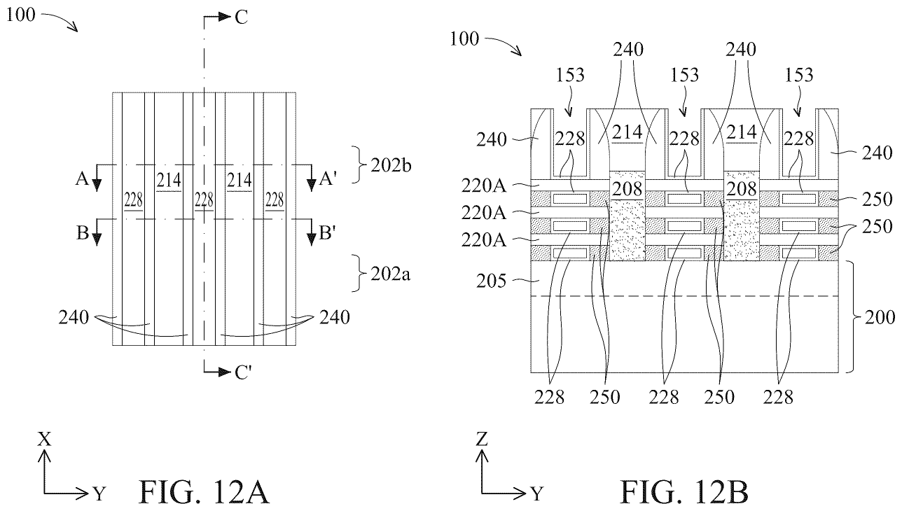

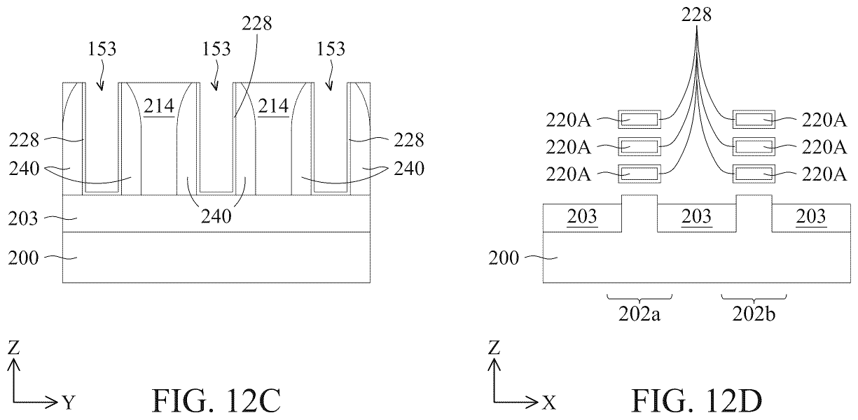

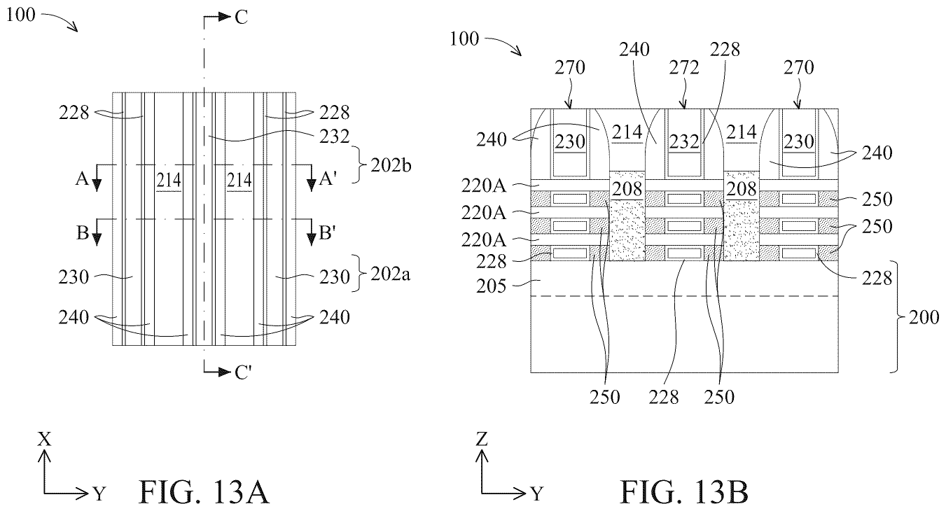

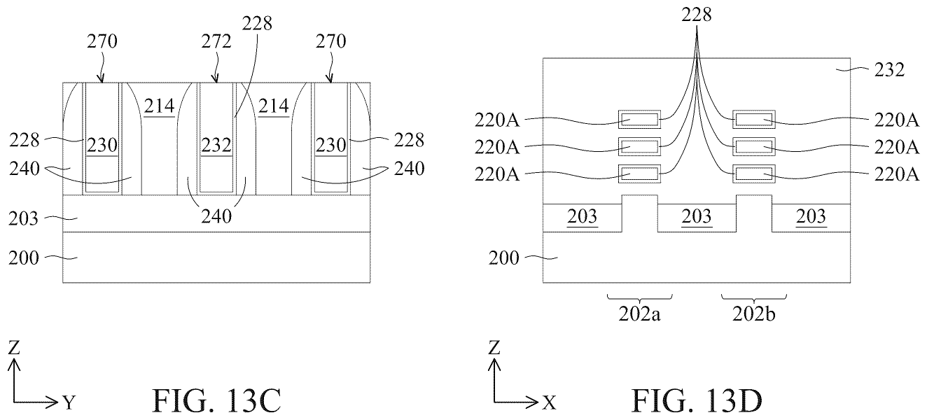

Referring to blocks 930 and 940 of FIG. 1C, FIGS. 12A-12D, and FIGS. 13A-13D, a gate structure is formed. The gate structure includes a gate dielectric layer, and a gate electrode disposed over the gate dielectric layer. For example, the gate structure may include a polysilicon gate electrode over a SiON gate dielectric layer. As another example, the gate structure may include a metal gate electrode over a high-k dielectric layer. In some instances, a refractory metal layer may interpose between the metal gate electrode (such as an aluminum gate electrode) and the high-k dielectric layer. As yet another example, the gate structure may include silicide. In the depicted embodiment, the gate structures each include a gate dielectric layer 228 and a gate electrode that includes one or more metal layers 230, 232, as illustrated in FIG. 13A~13D. The gate dielectric layers 228 are formed between the metal layers 230, 232 and the channels (the semiconductor layers 220A).

In some embodiments, the gate dielectric layers 228 are formed conformally on the device structure 100 (see FIGS. 12A-12D). The gate dielectric layers 228 at least partially fill the gate trenches 153. In some embodiments, dielectric interfacial layers may be formed over the semiconductor layers 220A prior to forming the gate dielectric layers 228. Such dielectric interfacial layers improve the adhesion between the semiconductor layers 220A and the gate dielectric layers 228. In the examples depicted in this disclosure, such dielectric interfacial layers are omitted. Instead, in the embodiments shown, the gate dielectric layers 228 is formed around the exposed surfaces of each of the semiconductor layers 220A, such that they wrap around each of the semiconductor layers 220A in 360 degrees. Additionally, the gate dielectric layers 228 also directly contact sidewalls of the inner spacers 250 and sidewalls of the top spacers 240. The gate dielectric layers 228 may include a dielectric material having a dielectric constant greater than a dielectric constant of SiO₂, which is approximately 3.9. For example, the gate dielectric layers 228 may include hafnium oxide (HfO₂), which has a dielectric constant in a range from about 18 to about 40. As various other examples, the gate dielectric layers 228 may include ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof. The formation of the gate dielectric layers 228 may be by any suitable processes, such as CVD, PVD, ALD, or combinations thereof.

Referring to block 940 of FIG. 1C and FIGS. 13A-13D, metal layers 230, 232 are formed over the gate dielectric layers 228 to fill the remaining spaces of the gate trenches 153. The metal layers 230, 232 may include any suitable materials, such as titanium nitride (TiN), tantalum nitride (TaN), titanium aluminide (TiAl), titanium aluminum nitride (TiAlN), tantalum aluminide (TaAl), tantalum aluminum nitride (TaAlN), tantalum aluminum carbide (TaAlC), tantalum carbonitride (TaCN), aluminum (Al), tungsten (W), copper (Cu), cobalt (Co), nickel (Ni), platinum (Pt), or combinations thereof. In some embodiments, a CMP is performed to expose a top surface of the ILD layer 214. The gate dielectric layers 228 and the metal layers 230 collectively form the gate structures 270, while the dielectric layers 228 and the metal layers 232 collectively form gate structure 272. Each of the gate structures 270, 272 engages multiple channel layers 220A.

The gate electrode may include Ti, Ag, Al, TiAlN, TaC, TaCN, TaSiN, Mn, Zr, TiN, TaN, Ru, Mo, Al, WN, Cu, W, Ru, Co, or any suitable conductive materials. In some embodiments, different metal materials are used for pFET and nFET devices with respective work functions to enhance device performance and reduce threshold voltages. For example, gate structure 270 is a gate structure of pFET devices and gate structure 272 is a gate structure of nFET devices.

The gate electrode may include multiple conductive materials, such as a work function metal layer different for pFET and nFET devices, and a fill metal layer. In some embodiments, the gate electrode includes a capping layer, a blocking layer, a work function metal layer, and a filling metal layer. In furtherance of the embodiments, the capping layer includes titanium nitride, tantalum nitride, or other suitable material, formed by a proper deposition technique such as ALD. The blocking layer includes titanium nitride, tantalum nitride, or other suitable material, formed by a proper deposition technique such as ALD. In various embodiments, the filling metal layer includes aluminum, tungsten, copper or other suitable metal. The filling metal layer is deposited by a suitable technique, such as PVD, plating or a combination thereof.

The work functional metal layer includes a conductive layer of metal or metal alloy with proper work function such that the corresponding FET is enhanced for its device performance. The work function (WF) metal layer is different in composition for a pFET device and a nFET device, therefore being referred to as an p-type WF metal and a n-type WF metal, respectively. Particularly, an n-type WF metal is a metal having a first work function such that the threshold voltage of the associated nFET is reduced. The n-type WF metal is close to the silicon conduction band energy (Ec) or lower work function, presenting easier electron escape. For example, the n-type WF metal has a work function of about 4.2 eV or less. A p-type WF metal is a metal having a second work function such that the threshold voltage of the associated pFET is reduced. The p-type WF metal is close to the silicon valence band energy (Ev) or higher work function, presenting strong electron bonding energy to the nuclei. For example, the p-type work function metal has a WF of about 5.2 eV or higher. In some embodiments, the n-type WF metal includes tantalum (Ta). In other embodiments, the n-type WF metal includes titanium aluminum (TiAl), titanium aluminum nitride (TiAlN), or combinations thereof. In other embodiments, the n-metal include Ta, TiAl, TiAlN, tungsten nitride (WN), or combinations thereof. In some embodiments, the p-type WF metal includes titanium nitride (TiN) or tantalum nitride (TaN). In other embodiments, the p-metal includes TiN, TaN, tungsten nitride (WN), titanium aluminum (TiAl), or combinations thereof. The work function metal is deposited by a suitable technique, such as PVD. The n-type WF metal or the p-type WF metal may include various metal-based films as a stack for optimized device performance and processing compatibility.

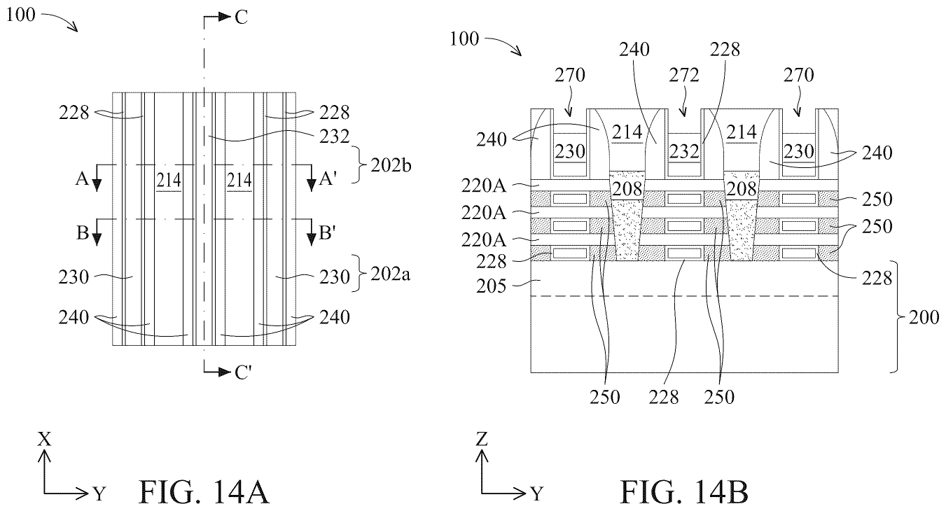

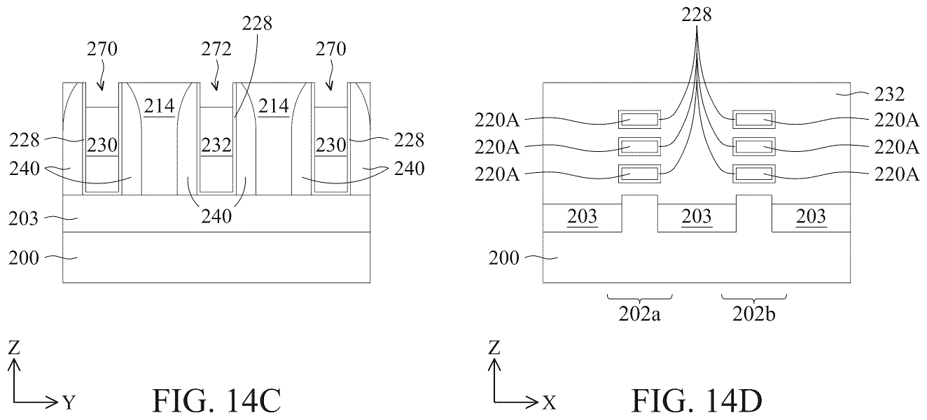

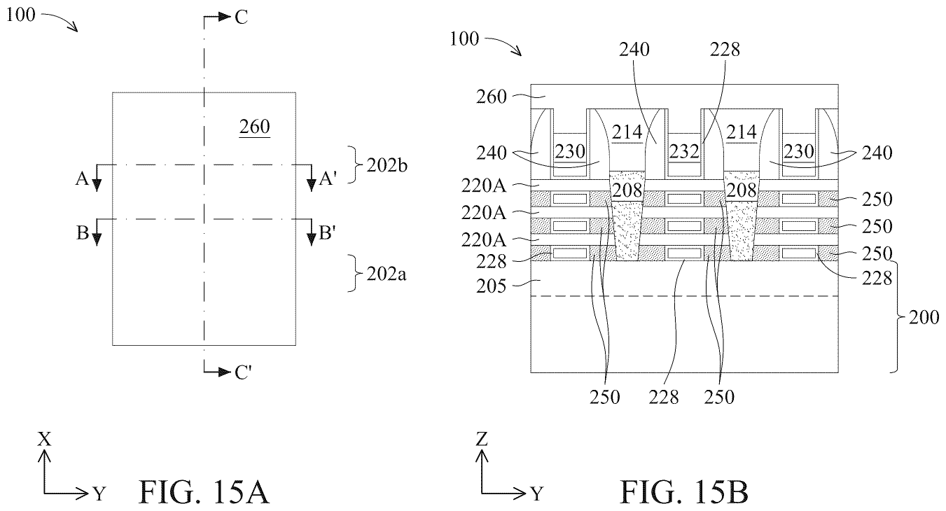

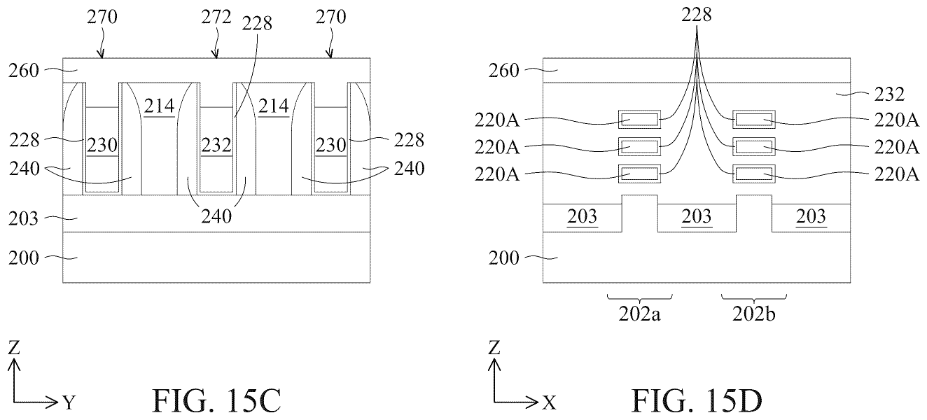

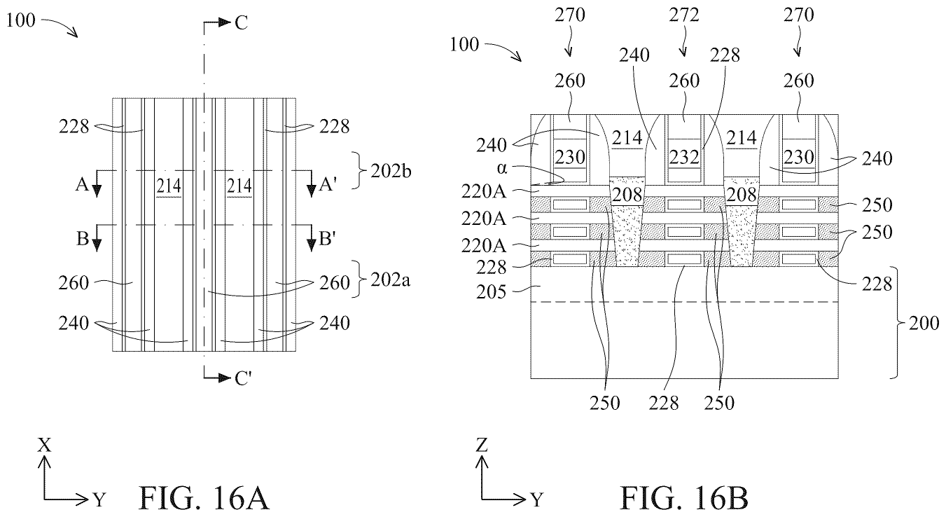

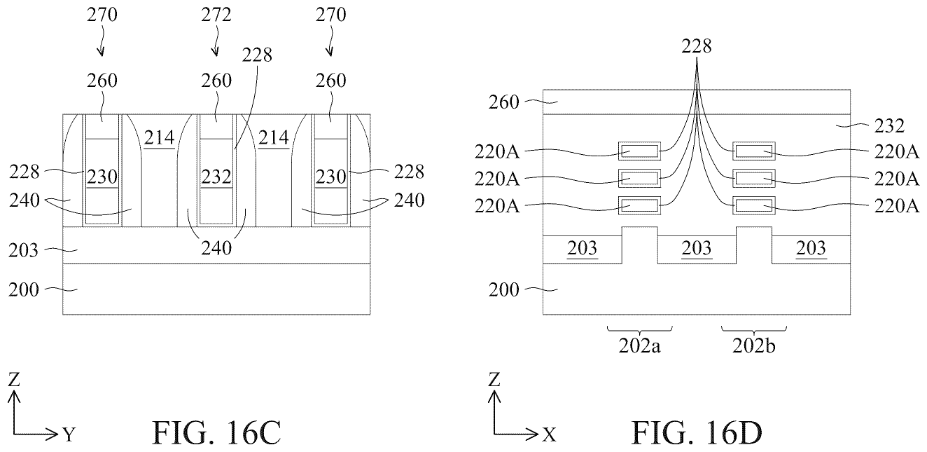

In some embodiments, a gate top hard mask layer may optionally be formed over the gate structures 270, 272, such as those described in FIGS. 14A-15D. For example, referring to FIGS. 14A-14D, the metal layers 230, 232 may optionally be recessed, such that a top surface of the metal layers 230, 232 extends below a top surface of the ILD layer 214. Subsequently, as illustrated in FIGS. 15A-15D, a gate top hard mask layer 260 is formed over the device structure 100 such that it covers the gate structures 270, 272 (specifically, the metal layers 230, 232), the ILD layers 214, and fills the space created by the recess process. A CMP may be conducted to planarize the top surface of the gate top hard mask layer 260. In some embodiments, as illustrated in FIGS. 16A-16D, the CMP exposes the top surfaces of the ILD layers 214, the top surfaces of the top spacers 240, and the top surfaces of the gate dielectric layers 228. The gate top hard mask layers 260 may include a dielectric material, such as SiO₂, SiOC, SiON, SiOCN, nitride-based dielectric, metal oxide dielectric, HfO₂, Ta₂O₅, TiO₂, ZrO₂, Al₂O₃, Y₂O₃, or combinations thereof. The gate top hard mask layer 260 protects the gate structures 270, 272 in the subsequent etching processes to form the source/drain contact features, and also insulates the gate structures 270, 272. However, in some other embodiments (not shown), recessing of the metal layers 230, 232 and/or the formation of the gate top hard mask layers 260 is omitted. In some embodiments, gate structure 270 is a gate structure of pFET devices and gate structure 272 is a gate structure of nFET devices.

The method 800 may include other processing steps implemented before, during and/or after the various operations described above. For example, the method 800, at a block 950 of FIG. 1D, includes forming an interconnect structure to connect various FETs and other devices into an integrated circuit. The interconnect structure includes contacts, vias and metal lines through a suitable process. In the copper interconnect structure, the conductive features include copper and may further include a barrier layer. The copper interconnect structure is formed by a damascene process. A damascene process includes depositing an ILD layer; patterning the ILD layer to form trenches; depositing various materials (such as a barrier layer and copper); and performing a CMP process. A damascene process may be a single damascene process or a dual damascene process. The deposition of the copper may include PVD to form a seed layer and plating to form bulk copper on the copper seed layer. Other metals, such as ruthenium, cobalt, tungsten or aluminum, may be used to form the interconnection structure. In some embodiments, prior to filling conductive material in contact holes, silicide may be formed on the sources and drains to further reduce the contact resistance. The silicide includes silicon and metal, such as titanium silicide, tantalum silicide, nickel silicide or cobalt silicide. Silicide may be formed by a process referred to as self-aligned silicide (or salicide). The process includes metal deposition, annealing to react metal with silicon, and etching to remove unreacted metal. In some other embodiments, some other metal, such as ruthenium or cobalt, may be used for contacts and/or vias.

The present disclosure provides a semiconductor structure having GAA structure and a method making the same with designed annealing processes and formation of source/drain feature. Especially, the method includes performing a laser spiking annealing process to the epitaxial grown source/drain feature; performing an ion implantation process to the source/drain feature; and performing a rapid thermal annealing process to the source/drain feature. Though not intended to be limiting, embodiments of the present disclosure offer benefits for semiconductor processing and semiconductor devices. For example, the disclosed method Various annealing processes are performed to activate the dopants in the epitaxial source/drain features, reduce channel resistance and source/drain resistance, reduce the channel length variation and improve the device performance.

In one example aspect, the present disclosure provides a method of semiconductor fabrication. The method includes forming a first active region and a second active region in a first area and a second area of a substrate respectively, wherein each of the first active region and the second active region includes channel layers and sacrificial layers alternatingly stacked; forming an isolation feature disposed between the first and second active regions; recessing portions of the first active region and the second active region to form a first recess and a second recess, respectively; epitaxially growing a first-type source/drain feature in the first recess; epitaxially growing a second-type source/drain feature in the second recess; forming a block layer to cover the first-type source/drain feature and the second-type source/drain feature; performing a laser annealing process to the second-type source/drain feature; forming a patterned mask layer over the block layer and covering the first-type source/drain feature; performing an ion implantation process to introduce a dopant into the second-type source/drain feature; and performing a rapid thermal annealing process to the first-type and second-type source/drain features, wherein the second-type source/drain feature includes two epitaxial semiconductor layers with different doping concentration.

In another example aspect, the present disclosure provides a method of semiconductor fabrication. The method includes forming an active region on a substrate, wherein the active region includes channel layers and sacrificial semiconductor layers alternatingly stacked; forming an isolation feature adjacent active region, the isolation feature including an oxide-based material; forming a dummy gate stack over the active region and the isolation feature; forming gate spacers on sidewalls of the dummy gate stack; recessing the active region in a source/drain region to form a source/drain recess; removing the sacrificial semiconductor layers, resulting in first gaps; forming dielectric interposers in the first gaps; laterally recessing the dielectric interposers to form second gaps; forming inner spacers in the second gaps; epitaxially growing a source/drain feature in the source/drain recess; forming a block layer to cover the source/drain feature; performing a first annealing process to the source/drain feature with a first annealing duration; performing an ion implantation process to introduce a dopant into the source/drain feature; performing a second annealing process to the source/drain features with a second annealing duration greater than the first annealing duration; and forming a gate stack wrap around the channel layers, wherein the gate stack includes a gate dielectric layer and a gate electrode on the gate dielectric layer and wherein the gate dielectric layer includes a dielectric constant greater than that of the gate spacers.

In yet another example aspect, the present disclosure provides a method of semiconductor fabrication. The method includes forming an active region on a substrate, wherein the active region includes channel layers and sacrificial semiconductor layers alternatingly stacked; forming an isolation feature disposed adjacent the active region, the isolation feature including an oxide-based material; forming a dummy gate stack over the active region and the isolation feature; forming gate spacers on sidewalls of the dummy gate stack; recessing the active region in a source/drain region to form a source/drain recess; removing the sacrificial semiconductor layers, resulting in first gaps; forming dielectric interposers in the first gaps; laterally recessing the dielectric interposers to form second gaps; forming inner spacers in the second gaps; epitaxially growing a source/drain feature in the first recess; forming a block layer to cover the source/drain feature; performing a first annealing process to the second-type source/drain feature with a first annealing temperature; exposing the source/drain feature to dopants; performing a second annealing process to the source/drain features with a second annealing temperature less than the first annealing temperature; and forming a gate stack wrap around the channel layers, wherein the gate stack extends from the channel layers to the isolation feature, and wherein the source/drain feature includes two epitaxial semiconductor layers with different doping concentration.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a first active region and a second active region in a first area and a second area of a substrate respectively, wherein each of the first active region and the second active region includes channel layers and sacrificial layers alternatingly stacked;
forming an isolation feature disposed between the first and second active regions;
recessing portions of the first active region and the second active region to form a first recess and a second recess, respectively;
epitaxially growing a first-type source/drain feature in the first recess;
epitaxially growing a second-type source/drain feature in the second recess;
forming a block layer to cover the first-type source/drain feature and the second-type source/drain feature;
performing a laser annealing process to the second-type source/drain feature;
forming a patterned mask layer over the block layer and covering the first-type source/drain feature;
performing an ion implantation process to introduce a dopant into the second-type source/drain feature; and
performing a rapid thermal annealing process to the first-type and second-type source/drain features, wherein the second-type source/drain feature includes two epitaxial semiconductor layers with different doping concentration.

2. The method of claim 1, wherein
the performing of the laser annealing process includes performing a laser spike annealing process with a first annealing temperature and a first annealing duration;
the performing of the rapid thermal annealing process includes performing the rapid thermal annealing process with a second annealing temperature and a second annealing duration; and
the second annealing temperature is less than the first annealing temperature and the second annealing duration is greater than the first annealing duration.

3. The method of claim 2, wherein
the performing of the laser spike annealing process includes performing the laser spike annealing process with the first annealing duration ranging between 0.2 ms and 1 ms; and
the performing of the rapid thermal annealing process includes performing the rapid thermal annealing process with the second annealing duration ranging between 1 s and 60 s.

4. The method of claim 3, wherein
the performing of the laser spike annealing process includes performing the laser spike annealing process in nitrogen (N₂) environment of an atmosphere pressure and with the first annealing temperature ranging between 800° C. to 1300° C.; and
the performing of the rapid thermal annealing process includes performing the rapid thermal annealing process with a pressure ranging between 1 Torr and 760 Torr and with the second annealing temperature ranging between 500° C. to 1200° C.

5. The method of claim 1, wherein the epitaxially growing of the second-type source/drain feature includes
epitaxially growing a first silicon layer doped with arsenic of a first doping concentration; and
epitaxially growing a second silicon layer doped with phosphorous of a second doping concentration greater than the first doping concentration.

6. The method of claim 5, wherein
the first doping concentration is less than or equal to 2*10²⁰ (at %); and
the first doping concentration is greater than or equal to 0.5*10²¹ (at %).

7. The method of claim 5, wherein
the first doping concentration ranges between 0.5*10²⁰ (at %) and 2*10²⁰ (at %); and
the first doping concentration ranges between 0.5*10²¹ (at %) and 2*10²¹ (at %).

8. The method of claim 5, wherein
the first silicon layer includes a plurality of silicon islands disposed on sidewalls of the channel layers; and
the second silicon layer is disposed on the silicon islands and separates the silicon islands from each other.

9. The method of claim 1, before the epitaxially growing of the first-type source/drain feature. further comprising
removing the sacrificial layers from the first recess and the second recess, resulting in first gaps between the channel layers;
forming dielectric interposers between the channel layers;
laterally recessing the dielectric interposers to form second gaps; and
forming inner spacers in the second gaps.

10. The method of claim 9, further comprising:
forming a dummy gate stack over the first and second active regions before the recessing of the first active region and the second active region;
forming an interlayer dielectric layer on the first-type source/drain feature and the second-type source/drain feature after the recessing of the first active region and the second active region;
removing the dummy gate stack, resulting in a gate trench in the interlayer dielectric layer;
removing the dielectric interposer; and
forming a gate stack wrapping around the channel layers.

11. The method of claim 1, further comprising:
forming an undoped semiconductor layer in the first and second recesses before the epitaxially growing of the first-type source/drain feature in the first recess.

12. The method of claim 11, further comprising:
forming a bottom isolation feature on the undoped semiconductor layer before the epitaxially growing of the first-type source/drain feature in the first recess.

13. A method for forming a semiconductor device, comprising:
forming an active region on a substrate, wherein the active region includes channel layers and sacrificial semiconductor layers alternatingly stacked;
forming an isolation feature adjacent active region, the isolation feature including an oxide-based material;
forming a dummy gate stack over the active region and the isolation feature;
forming gate spacers on sidewalls of the dummy gate stack;
recessing the active region in a source/drain region to form a source/drain recess;
removing the sacrificial semiconductor layers, resulting in first gaps;
forming dielectric interposers in the first gaps;
laterally recessing the dielectric interposers to form second gaps;
forming inner spacers in the second gaps;
epitaxially growing a source/drain feature in the source/drain recess;
forming a block layer to cover the source/drain feature;
performing a first annealing process to the source/drain feature with a first annealing duration;
performing an ion implantation process to introduce a dopant into the source/drain feature;
performing a second annealing process to the source/drain features with a second annealing duration greater than the first annealing duration; and
forming a gate stack wrap around the channel layers, wherein the gate stack includes a gate dielectric layer and a gate electrode on the gate dielectric layer and wherein the gate dielectric layer includes a dielectric constant greater than that of the gate spacers.

14. The method of claim 13, wherein
the performing of the first annealing process includes performing a laser spike annealing process with a first annealing temperature;
the performing of the second annealing process includes performing a rapid thermal annealing process with a second annealing temperature; and
the second annealing temperature is less than the first annealing temperature.

15. The method of claim 14, wherein
the performing of the laser spike annealing process includes performing the laser spike annealing process with the first annealing duration ranging between 0.2 ms and 1 ms; and
the performing of the rapid thermal annealing process includes performing the rapid thermal annealing process with the second annealing duration ranging between 1 s and 60 s.

16. The method of claim 15, wherein
the performing of the laser spike annealing process includes performing the laser spike annealing process in nitrogen (N₂) environment of an atmosphere pressure and with the first annealing temperature ranging between 800° C. to 1300° C.; and
the performing of the rapid thermal annealing process includes performing the rapid thermal annealing process with a pressure ranging between 1 Torr and 760 Torr and with the second annealing temperature ranging between 500° C. to 1200° C.

17. The method of claim 13, wherein the epitaxially growing of the source/drain feature includes
epitaxially growing a first semiconductor layer doped with arsenic of a first doping concentration; and
epitaxially growing a second semiconductor layer doped with phosphorous of a second doping concentration greater than the first doping concentration.

18. The method of claim 17, wherein the first doping concentration is less than or equal to 2*10²⁰ (at %); and
the first doping concentration is greater than or equal to 0.5*10²¹ (at %).

19. A method for forming a semiconductor device, comprising:
forming an active region on a substrate, wherein the active region includes channel layers and sacrificial semiconductor layers alternatingly stacked;
forming an isolation feature disposed adjacent the active region, the isolation feature including an oxide-based material;
forming a dummy gate stack over the active region and the isolation feature;
forming gate spacers on sidewalls of the dummy gate stack;
recessing the active region in a source/drain region to form a source/drain recess;
removing the sacrificial semiconductor layers, resulting in first gaps;
forming dielectric interposers in the first gaps;
laterally recessing the dielectric interposers to form second gaps;
forming inner spacers in the second gaps;
epitaxially growing a source/drain feature in the first recess;
forming a block layer to cover the source/drain feature;
performing a first annealing process to the second-type source/drain feature with a first annealing temperature;
exposing the source/drain feature to dopants;
performing a second annealing process to the source/drain features with a second annealing temperature less than the first annealing temperature; and
forming a gate stack wrap around the channel layers, wherein the gate stack extends from the channel layers to the isolation feature, and wherein the source/drain feature includes two epitaxial semiconductor layers with different doping concentration.

20. The method of claim 19, wherein
the performing of the first annealing process includes performing a laser spike annealing process with the first annealing duration ranging between 0.2 ms and 1 ms;
the performing of the second annealing process includes performing a rapid thermal annealing process with the second annealing duration ranging between 1 s and 60 s;
the epitaxially growing of the source/drain feature includes epitaxially growing a first semiconductor layer doped with arsenic of a first doping concentration less than or equal to 2*10²⁰ (at %), and epitaxially growing a second semiconductor layer doped with phosphorous of a second doping concentration greater than or equal to 0.5*10²¹ (at %).
